(19) United States
(12) Patent Application Publication
(10) Pub. No.: US 2014/0138799 A1
(43) Pub. Date: May 22, 2014

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Won-keun KIM, Hwaseong-si (KR); Sang-Wook PARK, Hwaseong-si (KR)

(73) Assignee: SAMSUNG ELECTRONICS CO., LTD., Suwon-Si (KR)

(21) Appl. No.: 14/062,201

(22) Filed: Oct. 24, 2013

(30) Foreign Application Priority Data
Nov. 20, 2012 (KR) 10-2012-0131940

(51) Int. Cl. H01L 23/538

(52) U.S. Cl. CPC H01L 23/5384
USPC 257/621

(57) ABSTRACT

Semiconductor packages capable of reducing a total height thereof and methods of manufacturing the semiconductor package are provided. The semiconductor package includes a semiconductor substrate having first and second surfaces opposite to each other, a semiconductor device formed on the first surface of the semiconductor substrate, pads formed on the first surface of the semiconductor substrate and electrically connected to the semiconductor device, and at least one printed circuit layer including a resin layer, via electrodes penetrating through the resin layer, and line layers formed on the first resin layer and connected to the via electrodes and attached onto the first surface of the semiconductor substrate. The via electrodes and the line layers are formed of the same type of material, and the via electrodes are electrically connected to the pads.

### CROSS-REFERENCE TO RELATED APPLICATIONS

This application claims priority under 35 U.S.C. §119 to Korean Patent Application No. 10-2012-0131940, filed on Nov. 20, 2012, in the Korean Intellectual Property Office, the disclosure of which is incorporated herein in its entirety by reference.

### BACKGROUND

The inventive concepts relate to semiconductor packages and methods of manufacturing the same, and more particularly, to semiconductor packages capable of reducing a total height thereof and methods of manufacturing the same.

Electronic devices have been made smaller and lighter and have had multi-functions with the fast development of the electronic industry and demand of users.

Accordingly, semiconductor packages used in electronic devices are required to be smaller and lighter and have multi-functions. However, in a semiconductor package including a printed circuit board (PCB), a volume of the PCB and a volume necessary for attaching the PCB are greater than a volume of semiconductor devices included in the semiconductor package. Therefore, it is difficult to make a semiconductor package smaller when integrating thin semiconductor devices.

### SUMMARY

The inventive concepts provide semiconductor packages capable of reducing a total height thereof and methods of manufacturing the same.

According to example embodiments, a semiconductor package includes a first semiconductor chip having a first semiconductor substrate having a first active surface and a first inactive surface opposite to each other, a first semiconductor device formed on the first active surface of the first semiconductor substrate, first through electrodes penetrating through the first semiconductor substrate, and pads electrically connected to one of the first semiconductor device and the first through electrodes, a printed circuit structure on the first semiconductor chip, the printed circuit structure including at least one printed circuit layer having a resin layer having upper and lower surfaces opposite to each other, the lower surface of the resin layer facing the first active surface of the first semiconductor substrate, via electrodes penetrating through the resin layer to be electrically connected to the first semiconductor chip, and line layers formed on the upper surface of the resin layer and connected to the via electrodes, a second semiconductor chip attached to the first semiconductor chip and facing the first inactive surface of the first semiconductor substrate and electrically connected to the first through electrodes, and external connection terminals attached to a surface of the printed circuit structure and electrically connected to the line layers and the via electrodes.

The via electrodes and the line layers may include a same type of material. The via electrodes may be electrically connected to the pads.

The printed circuit layer may include reinforcement fillers dispersed in the resin layer.

The lower surface of resin layer may surface-contacts the first semiconductor chip.

The printed circuit structure may further include a solder resist layer that covers the surface of the printed circuit structure that is opposite to the surface of the printed circuit structure facing the first semiconductor chip while exposing portions of the line layers.

The external connection terminals may be connected to the portions of the line layers exposed through the solder resist layer.

The second semiconductor chip may include a second active surface having a second semiconductor device thereon and the second active surface electrically connected to the first semiconductor chip through connection bumps, and a second inactive surface opposite to the second active surface.

The first active surface of the first semiconductor chip may have a same area as the second active surface of the second semiconductor chip.

An area of the first active surface of the first semiconductor chip may be greater than an area of the second active surface of the second semiconductor chip.

The second semiconductor chip may include a second semiconductor substrate having a second active surface and a second inactive surface opposite to each other, a second semiconductor device formed on the second active surface, and second through electrodes penetrating through the second semiconductor substrate from the second active surface to the second inactive surface. The semiconductor package may further include a third semiconductor chip attached to the second semiconductor chip and electrically connected to the second through electrodes.

According to example embodiments, a semiconductor package may include a semiconductor substrate having first and second surfaces opposite to each other, a semiconductor device formed on the first surface of the semiconductor substrate, pads formed on the first surface of the semiconductor substrate and electrically connected to the semiconductor device, and at least one printed circuit layer including a resin layer, via electrodes penetrating through the resin layer, and line layers on the first resin layer, the line layer connected to the via electrodes and attached to the first surface of the semiconductor substrate. The via electrodes and the line layers may include a same type of material, and the via electrodes may be electrically connected to the pads.

The via electrodes and the line layers of the at least one printed circuit layer may directly contact the resin layer.

The via electrodes may directly contact the pads.

A plurality of printed circuit layers may be formed. Resin layers of two adjacent printed circuit layers of the plurality of printed circuit layers may surface-contact each other.

According to example embodiments, a semiconductor package may include a first semiconductor structure including a first semiconductor substrate, the first semiconductor substrate including a first though electrode penetrating therethrough, the first through electrode including a first end and a second end opposite to each other, a first printed circuit layer on the first semiconductor structure, the first printed circuit layer electrically connected to the first end of the first through electrode, a second printed circuit layer on the first printed circuit layer, the second printed circuit layer electrically connected to the first through electrode, and a second semiconductor structure electrically connected to the second end of the first through electrode.

At least one of the first and the second printed circuit layer may include a resin layer on the first semiconductor structure including a through hole, and a line layer structure configured to fill the through hole.

The line layer may include a via electrode portion filling the through hole, and a line layer portion on the via electrode portion and extending over an upper surface of the resin layer.

The line layer portion may include a copper clad layer and a first plating layer on the copper clad layer.

The semiconductor package may further include a front pad on the first end of the first through electrode, the front pad configured to electrically connect the first end of the first through electrode to the first semiconductor structure.

The semiconductor package may further include a back pad on the second end of the first through electrode, the back pad configured to electrically connect the second end of the first through electrode to the second semiconductor structure.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view illustrating a semiconductor package according to example embodiments of the inventive concepts;

FIG. 2 is a cross-sectional view illustrating a semiconductor package according to example embodiments of the inventive concepts;

FIG. 3 is a cross-sectional view illustrating a semiconductor package according to example embodiments of the inventive concepts;

FIG. 4 is a cross-sectional view illustrating a semiconductor package according to example embodiments of the inventive concepts;

FIG. 5 is a cross-sectional view illustrating a semiconductor package according to example embodiments of the inventive concepts;

FIG. 6 is a cross-sectional view illustrating a process of providing a first wafer on which a first semiconductor device is formed, according to example embodiments of the inventive concepts;

FIG. 7 is a cross-sectional view illustrating a process of attaching a first copper clad laminate, according to example embodiments of the inventive concepts;

FIG. 8 is a cross-sectional view illustrating a process of forming first through holes, according to example embodiments of the inventive concepts;

FIG. 9 is a cross-sectional view illustrating a process of forming a first plating layer, according to example embodiments of the inventive concepts;

FIG. 10 is a cross-sectional view illustrating a process of forming a first printed circuit layer, according to example embodiments of the inventive concepts;

FIG. 11 is a cross-sectional view illustrating a process of attaching a second copper clad laminate, according to example embodiments of the inventive concepts;

FIG. 12 is a cross-sectional view illustrating a process of forming second through holes, according to example embodiments of the inventive concepts;

FIG. 13 is a cross-sectional view illustrating a process of forming a second plating layer, according to example embodiments of the inventive concepts;

FIG. 14 is a cross-sectional view illustrating a process of exposing first through electrodes, according to an example embodiments of the inventive concepts;

FIG. 15 is a cross-sectional view illustrating a process of attaching a second semiconductor chip, according to example embodiments of the inventive concepts;

FIG. 16 is a cross-sectional view illustrating a process of forming a mold layer, according to example embodiments of the inventive concepts;

FIG. 17 is a cross-sectional view illustrating a process of forming a printed circuit structure, according to example embodiments of the inventive concepts;

FIG. 18 is a cross-sectional view illustrating a process of forming external connection terminals, according to example embodiments of the inventive concepts;

FIG. 19 is a cross-sectional view illustrating a method of manufacturing a semiconductor package, according to example embodiments of the inventive concepts;

FIG. 20 is a cross-sectional view illustrating a process of forming a printed circuit structure, according to example embodiments of the inventive concepts;

FIG. 21 is a cross-sectional view illustrating a process of forming a solder resist layer, according to example embodiments of the inventive concepts;

FIG. 22 is a cross-sectional view illustrating a process of forming a second semiconductor chip and a mold layer, according to example embodiments of the inventive concepts;

FIG. 23 is a cross-sectional view illustrating a semiconductor package according to example embodiments of the inventive concepts;

FIG. 24 is a cross-sectional view illustrating a method of manufacturing a semiconductor package, according to example embodiments of the inventive concepts;

FIG. 25 is a cross-sectional view illustrating a semiconductor package according to another exemplary embodiment of the inventive concept;

FIG. 26 is a cross-sectional view illustrating a semiconductor package according to example embodiments of the inventive concepts; and

FIG. 27 is a schematic block diagram illustrating a system including a semiconductor package, according to example embodiments of the inventive concepts.

### DETAILED DESCRIPTION OF THE EMBODIMENTS

The inventive concepts will now be described more fully with reference to the accompanying drawings, in which example embodiments of the inventive concepts are shown. The inventive concepts may, however, be embodied in many different forms and should not be construed as being limited to the embodiments set forth herein; rather, these embodiments are provided so that this disclosure will be thorough and complete, and will fully convey the inventive concepts to those skilled in the art. In the drawings, the sizes of elements are exaggerated for clarity, and ratios of the elements may be exaggerated or reduced.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

It will be understood that, although the terms ‘first’, ‘second’, etc. may be used herein to describe various elements, these elements should not be limited by these terms. These terms are only used to distinguish one element from another. For example, a first element could be termed a second element, and, similarly, a second element could be termed a first element, without departing from the scope of example embodiments.

As used herein, the singular forms “a”, “an”, and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the inventive concepts will be described in detail by explaining example embodiments of the inventive concepts with reference to the attached drawings.

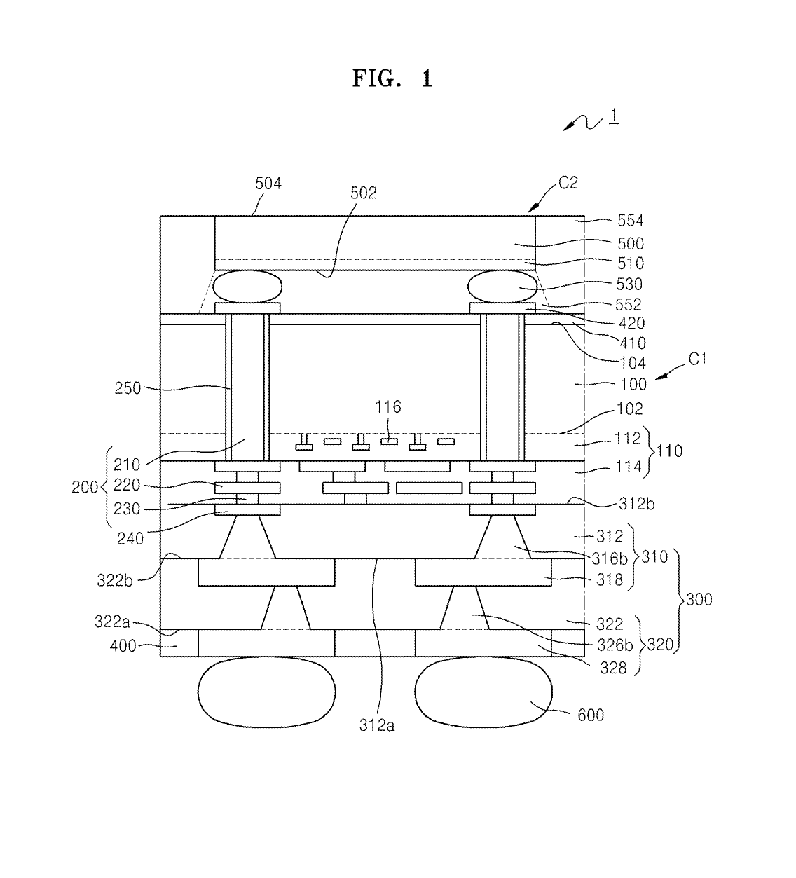

FIG. 1 is a cross-sectional view illustrating a semiconductor package 1 according to example embodiments of the present inventive concepts.

Referring to FIG. 1, the semiconductor package 1 may include a first semiconductor chip C1 and a second semiconductor chip C2. A printed circuit structure 300 may be attached to the first semiconductor chip C1. The second semiconductor chip C2 may be attached to the first semiconductor chip C1. The printed circuit structure 300 and the second semiconductor chip C2 may be respectively attached onto opposite sides of the first semiconductor chip C1.

The first semiconductor chip C1 may include a first semiconductor substrate 100, a first semiconductor device 110, and first through electrodes 210. The first semiconductor substrate 100 may have a first active surface 102 and a first inactive surface 104 that are opposite to each other. The first semiconductor device 110 may be formed on the first active surface 102 of the first semiconductor substrate 100. The first through electrodes 210 may penetrate through the first semiconductor substrate 100. The first semiconductor chip C1 may further include first pads 240 that are electrically connected to the first through electrodes 210, respectively. The first semiconductor device 110 may include a front-end-of-line (FEOL) structure 112 and a back-end-of-line (BEOL) structure 114 formed on the FEOL structure 112.

A thickness of the first semiconductor substrate 100 mostly occupies a thickness of the first semiconductor chip C1, and a thickness of the first semiconductor device 110 is much smaller than the thickness of the first semiconductor substrate 100. The first semiconductor device 110 may be formed inside the first semiconductor substrate 100 together. Therefore, the first active surface 102 and the first inactive surface 104 refer to opposite sides of the first semiconductor chip C1.

The first semiconductor substrate 100 may include silicon (Si). Alternatively, the first semiconductor substrate 100 may include a semiconductor element, such as germanium (Ge), or a compound semiconductor, such as silicon carbide (SiC), gallium arsenide (GaAs), indium arsenide (InAs), and indium phosphide (InP). The semiconductor substrate 100 may also have a silicon-on-insulator (SOI) structure. For example, the first semiconductor substrate 100 may include a buried oxide (BOX) layer. The first semiconductor substrate 100 may include a conductive area, e.g., a well doped with a dopant or a structure doped with a dopant. The first semiconductor substrate 100 may have various types of isolation structures, such as a shallow trench isolation (STI) structure.

The FEOL structure 112 may include a plurality of individual devices 116 of various types. The plurality of individual devices 116 may include various types of microelectronic devices, e.g., a complementary metal-insulator-semiconductor (CMOS) transistor, a metal-oxide-semiconductor field effect transistor (MOSFET), an image sensor such as a system large scale integration (LSI), a CMOS imaging sensor (CIS), or the like, a micro-electro-mechanical system (MEMS), an active device, a passive device, etc. The plurality of individual devices 116 may be electrically connected to the conductive area of the first semiconductor substrate 100. The FEOL structure 112 may further include at least two of the plurality of individual devices 116, or conductive lines or conductive plugs that electrically connect the plurality of individual devices 116 to the conductive area of the first semiconductor substrate 100. The plurality of individual devices 116 may be electrically isolated from each other through insulating layers, respectively.

The BEOL structure 114 may include a plurality of line structures 220 and 230 that connect the individual devices 116 formed in the FEOL structure 110 to other lines formed on the first semiconductor substrate 100. The plurality of line structures 220 and 230 may include metal line layers 220 and via plugs 230. The metal line layers 220 and the via plugs 230 may be formed of barrier layers used and metal layers. The barrier layers may include at least one material selected from Ti, TiN, Ta, and TaN. The metal layers may include at least one metal selected from W, Al, and Cu. The metal line layers 220 and the via plugs 230 may be formed of the same type of material. Alternatively, some of the metal line layers 220 and the via plugs 230 may include different types of materials. the metal line layers 220 and/or the via plugs 230 may form multilayer structures. In other words, the line structures 220 and 230 may be multilayer structures in which at least two or more metal line layers 220 and two or more via plugs 230 are alternately stacked. The BEOL structure 114 may further include a passivation layer that protects other structures formed under the line structures 220 and 230 from external shock or moisture

The first pads 240 may be formed on the BEOL structure 114, which is formed on the first active surface 102. The first pads 240 may be electrically connected to the line structures 220 and 230, respectively.

The first through electrodes 210 may penetrate through the first semiconductor substrate 100. The first through electrodes 210 may have pillar shapes that penetrate through the first semiconductor substrate 100. The first through electrodes 210 may include barrier layers formed on surfaces of the pillar shapes and buried conductive layers filling a space formed by the barrier layers. The barrier layers may include at least one material selected from Ti, TiN, Ta, TaN, Ru, Co, Mn, WN, Ni, and NiB, and the buried conductive layers may include at least one material selected from a Cu alloy, such as Cu, CuSn, CuMg, CuNi, CuZn, CuPd, CuAu, CuRe, CuW, or the like, W, a W alloy, Ni, Ru, and Co. First insulating layers 250 may be interposed between the first semiconductor substrate 100 and the first through electrodes 210. The first insulating layers 250 may be formed of oxide layers, nitride layers, carbide layers, or combinations thereof. The first insulating layers 250 may have a thickness between about 1500 Å and about 2500 Å.

The first through electrodes 210 may form through silicon via (TSV) structures 200 along with some of the metal line layers 220 and the via plugs 230. The TSV structures 200 may penetrate through the whole first semiconductor chip C1. The TSV structures 200 may be electrically connected to or electrically insulated from the first semiconductor device 110 inside the first semiconductor chip C1. For example, a plurality of TSV structures 200 may be formed, some of the plurality of TSV structures 200 may be electrically insulated from the first semiconductor device 110 inside the first semiconductor chip C1, and the other TSV structures 200 may be electrically connected to the first semiconductor device 110 inside the first semiconductor chip C1. Alternatively, all of the TSV structures 200 may be electrically insulated from or electrically connected to the first semiconductor device 110 inside the first semiconductor chip C1.

The first pads 240 may be electrically connected to the TSV structures 200. For example, a plurality of first pads 240 may be formed, some of the plurality of first pads 240 may be electrically connected to the line structures 220 and 230, some of which may not be electrically connected to the TSV structures 200 but may electrically connected to the first semiconductor device 110.

First back pads 420 may be formed on the first inactive surface 104 of the first semiconductor substrate 100 and electrically connected to the first through electrodes 210. A first back protective layer 410 may be formed on the inactive surface 104 of the first semiconductor substrate 100 to cover the inactive surface 104 of the first semiconductor substrate 100. The first back protective layer 410 may expose the first through electrodes 210, and the first back pads 420 are formed on the first through electrodes 210 exposed through the first back protective layer 410.

The printed circuit structure 300 may include at least one of printed circuit layers 310 and 320. For example, the printed circuit structure 300 may include two printed circuit layers 310 and 320, e.g., first and second printed circuit layers 310 and 320. The first and second printed circuit layers 310 and 320 may respectively include first and second resin layers 312 and 322, first and second via electrodes 316b and 326b, and first and second line layers 318 and 328. In other words, the first printed circuit layers 310 may include the first resin layer 312, the first via electrodes 316b, and the first line layers 318, and the second printed circuit layers 320 may include the second resin layer 322, the second via electrodes 326b, and the second line layers 328. The printed circuit structure 300 may include two printed circuit layers 310 and 320 as illustrated in FIG. 1. The printed circuit structure 300 may include one printed circuit layer, or three or more printed circuit layers.

The first via electrodes 316b and the first line layers 318 of the first printed circuit layers 310 may be electrically connected to the second via electrodes 326b and the second line layers 328 of the second printed circuit layers 320. The first via electrodes 316b may be electrically connected to the first pads 240. The first via electrodes 316b may contact the first pads 240.

The first resin layer 312 may have upper and lower surfaces 312a and 312b, and the first line layers 318 may be formed on the upper surface 312a of the first resin layer 312. The second resin layer 322 may have upper and lower surfaces 322a and 322b that are opposite to each other, and the second line layers 328 may be formed on the upper surface 322a of the second resin layer 322. The first and second printed circuit layers 310 and 320 may be attached to each other so that the upper surface 312a of the first resin layer 312 and the lower surface 322b of the second resin layer 322 face each other. The upper surface 312a of the first resin layer 312 and the lower surface 322b of the second resin layer 322 may surface-contact each other. The printed circuit structure 300 may be attached to the first semiconductor chip C1 so that the lower surface 312b of the first resin layer 312 faces the first active surface 102 of the first semiconductor substrate 100. The printed circuit structure 300 may directly contact the first semiconductor chip C1. In other words, the lower surface 312b of the first resin layer 312 may surface-contact the first semiconductor chip C1.

The first and second resin layers 312 and 322 may be formed of phenol, epoxy, polyimide, or the like. For example, the first and second resin layers 312 and 322 may include at least one material selected from FR4, tetrafunctional epoxy, polyphenylene ether, epoxy/polyphenylene oxide, bismaleimide triazine, thermount, cyanate ester, polyimide, and liquid crystal polymer

The first and second via electrodes 316b and 326b and the first and second line layers 318 and 328 may be formed of copper, nickel, stainless steel, or beryllium copper. The first via electrodes 316b and the first line layers 318 may be formed of the same type of material. The first via electrodes 316b and the first line layers 318 may be formed as single bodies. The second via electrodes 326b and the second line layers 328 may be formed of the same type of material. The second via electrodes 326b and the second line layers 328 may be formed as single bodies.

A solder resist layer 400 may further be formed to cover a surface of the printed circuit structure 300 that is opposite to a surface of the printed circuit structure 300 facing the first semiconductor chip C1, i.e., the upper surface 322a of the second resin layer 322, and may expose portions of the second line layers 328. The solder resist layer 400 may enclose sides of the second line layers 328. The solder resist layer 400 may cover portions of upper surfaces of the second line layers 328.

External connection terminals 600 may be formed on the surface of the printed circuit structure 300 that is opposite to the surface of the printed circuit structure 300 facing the first semiconductor chip C1, i.e., on the upper surface 322a of the second resin layer 322, and may be electrically connected to the first and second via electrodes 316b and 326b and the first and second line layers 318 and 328. The external connection terminals 600 may be attached to portions of the second line layers 328 of the second printed circuit layer 320 to provide electrical connecter between the second line layers 328 and the first semiconductor chip.

The second semiconductor chip C2 may be attached to the first semiconductor chip C1 to face the first inactive surface 104 of the first semiconductor substrate 100. The second semiconductor chip C2 may electrically connected to the first through electrodes 210. The second semiconductor chip C2 may include a second semiconductor substrate 500 having a second active surface 502 and a second inactive surface 504, and a second semiconductor device 510 formed on the second active surface 502 of the second semiconductor substrate 500. The second semiconductor device 510 may be electrically connected to the first through electrodes 210. The first and second semiconductor chips C1 and C2 may be attached to each other so that the first inactive surface 104 of the first semiconductor substrate 100 and the second active surface 502 of the second semiconductor substrate 500 face each other. The second semiconductor chip C2 may be attached to the first semiconductor chip C1 through connection bumps 530. The connection bumps 530 may be electrically connected to the second semiconductor device 510. The connection bumps 530 may contact the first back pads 420 to electrically connect the second semiconductor device 510 to the first through electrodes 210.

The second semiconductor chip C2 may have a smaller area than the first semiconductor chip C1. In other words, the second active surface 502 or the second inactive surface 504 of the second semiconductor substrate 500 may have a smaller area than the first active surface 102 or the first inactive surface 104 of the first semiconductor substrate 100. A mold layer 554 may be formed above the first inactive surface 104 of the first semiconductor substrate 100. The mold layer 554 may enclose the second semiconductor chip C2 to expose the second inactive surface 504 of the second semiconductor substrate 500. A first underfill layer 552 may be formed between the second semiconductor chip C2 and the first semiconductor chip C1 to fill a space between the first and second semiconductor chips C1 and C2. The first underfill layer 552 and the mold layer 554 may be formed of various types of materials. Alternatively, the first underfill layer 552 and the mold layer 554 may be formed of the same type of material.

If the area of the second semiconductor chip C2 is smaller than that of the first semiconductor chip C1, the other portion of the first inactive surface 104 of the first semiconductor substrate 100 except a portion of the first inactive surface 104 that is covered with the second semiconductor chip C2 may be covered with the mold layer 554. In other words, a total area of the mold layer 554 and the second semiconductor chip C2, e.g., a sum of an area of the second inactive surface 504 and an area of the mold layer 554 on the same plane as the second inactive surface 504 may be equal to the area of the first semiconductor chip C1, e.g., an area of the first inactive surface 104 of the first semiconductor substrate 100.

Although not shown in FIG. 1, the semiconductor package 1 may further include an encapsulating layer that protects both sides of the first semiconductor chip C1 and/or the second inactive surface 504 of the second semiconductor substrate 500.

In the semiconductor package 1, the printed circuit structure 300 may be attached to face a side of the first semiconductor chip C1, e.g., the first active surface 102 of the first semiconductor substrate 100, and the second semiconductor chip C2 is attached to face the other side of the first semiconductor chip C1, e.g., the first inactive surface 104 of the first semiconductor substrate 100. The printed circuit structure 300 may be directly attached onto the first semiconductor chip C1 to perform the same function as a printed circuit board (PCB). If a PCB is used, solder resist layers may be formed on both a side of the PCB facing the first semiconductor chip C1 and the other side opposite the side facing the first semiconductor chip C1. However, a solder resist layer may not be formed on a side of the printed circuit structure 300 of the semiconductor package 1 facing the first semiconductor chip C1, e.g., on the lower surface 312b of the first resin layer 312, and a solder resist layer may be formed on the other side of the printed circuit structure 300, e.g., on the upper surface 322a of the second resin layer 322. If a PCB is used, connection bumps and an underfill material filling a space between the first semiconductor chip C1 and the PCB may be required between the first semiconductor chip C1 and the PCB. However, if the printed circuit structure 300 is attached to directly surface-contact the first semiconductor chip C1, the connection bumps and the underfill material may not be used. Therefore, manufacturing cost may be reduced, and a total height of the semiconductor package 1 may be reduced. Because the connection bumps are not used, a fault in the semiconductor chip 1 caused by a contact fault of the connection bumps may be prevented or mitigated, thereby improving the reliability of the semiconductor package 1.

Because the connection bumps are not used, design features of a portion of the printed circuit structure 300, which is electrically connected to the first semiconductor chip C1, (e.g., pitches of the first via electrodes 316b, sections of the first via electrodes 316b, or gaps between a plurality of first via electrodes 316b) may be reduced. Therefore, if the first semiconductor chip C1 has the TSV structures 200, pitches of the TSV structures 200 may also be reduced. As a result, a semiconductor package using semiconductor chips having a wide Input/Output (I/O) requiring a larger number of TSV structures 200 may be realized.

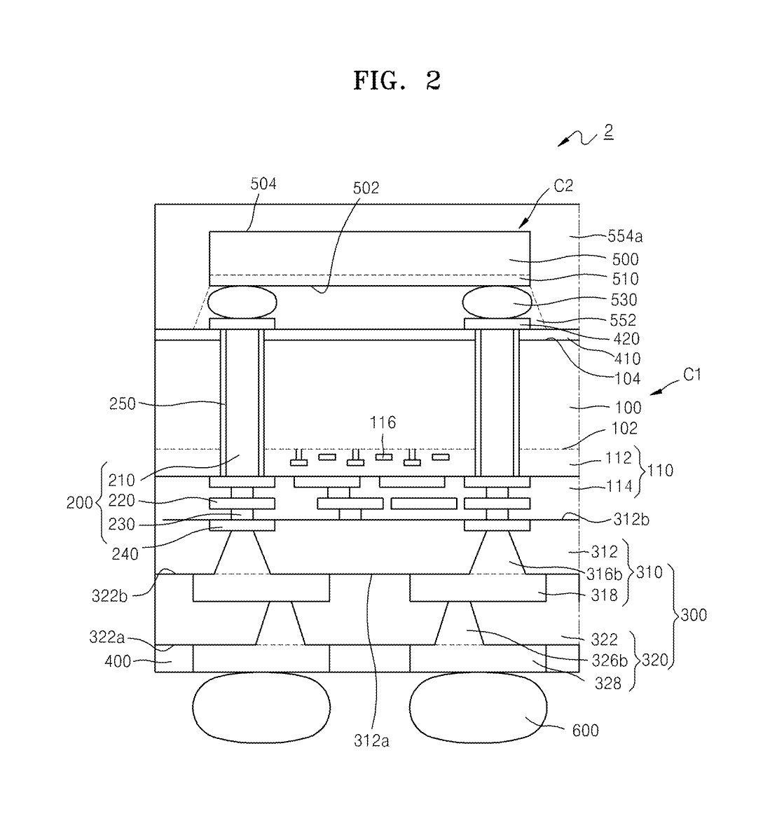

FIG. 2 is a cross-sectional view illustrating a semiconductor package 2 according to example embodiments of the inventive concepts. The same descriptions of the semiconductor package 2 of FIG. 2 as those of the semiconductor package 1 of FIG. 1 are omitted herein.

Referring to FIG. 2, the semiconductor package 2 may include a first semiconductor chip C1 and a second semiconductor chip C2. A printed circuit structure 300 may be attached onto the first semiconductor chip C1. The second semiconductor chip C2 may be attached onto the first semiconductor chip C1. The printed circuit structure 300 and the second semiconductor chip C2 may be respectively attached onto opposite surfaces of the first semiconductor chip C1.

A mold layer 554a may be formed on a first inactive surface 104 of a first semiconductor substrate 100. The mold layer 554a may also cover all portions of the second semiconductor chip C2.

In the semiconductor package 1 of FIG. 1, the second inactive surface 504 of the second semiconductor substrate 500 may be exposed through the mold layer 554. However, in the semiconductor package 2 of FIG. 2, a second inactive surface 504 of a second semiconductor substrate 500 of the second semiconductor chip C2 may be covered with the mold layer 554a. The total height of the semiconductor package 1 may be minimized, and a heat emission may be maximized through the exposed second inactive surface 504 of the second semiconductor substrate 500. However, because all portions of the second semiconductor chip C2 are covered with the mold layer 554a, the durability of the second semiconductor package 2 may be improved. Therefore, the semiconductor package 1 of FIG. 1 or the semiconductor package 2 of FIG. 2 may be selectively manufactured according to desired purposes.

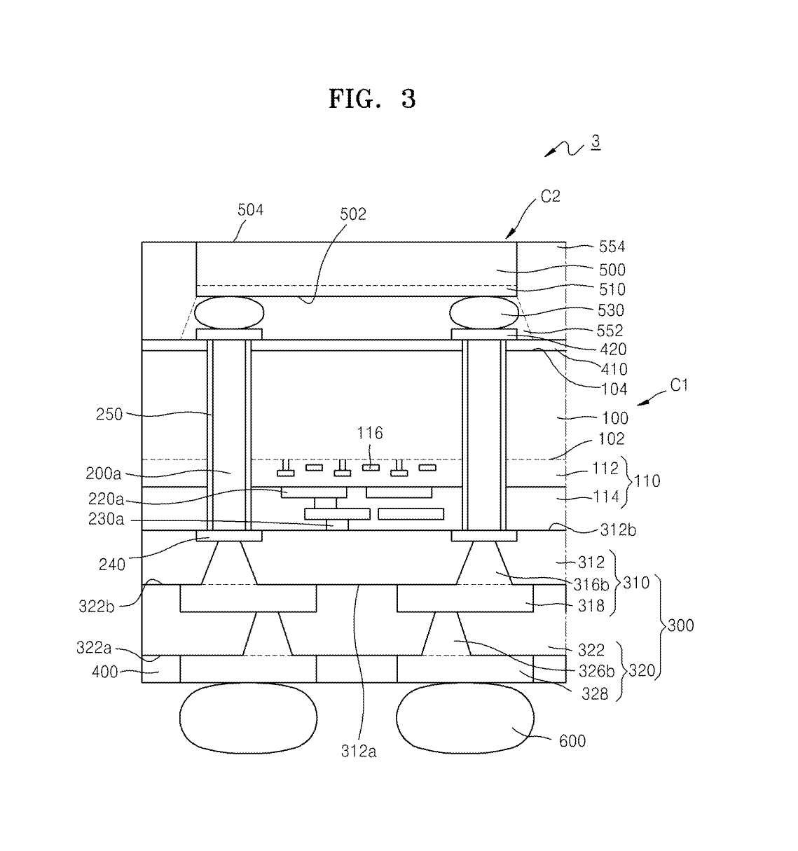

FIG. 3 is a cross-sectional view illustrating a semiconductor package 3 according to example embodiments of the inventive concepts. The same descriptions of the semiconductor package 3 of FIG. 3 as those of the semiconductor package 1 of FIG. 1 are omitted herein.

Referring to FIG. 3, the semiconductor package 3 may include first and second semiconductor chips C1 and C2. A printed circuit structure 300 may be attached onto the first semiconductor chip C1. The second semiconductor chip C2 may be attached onto the first semiconductor chip C1. The printed circuit structure 300 and the second semiconductor chip C2 may be respectively attached onto opposite surfaces of the first semiconductor chip C1.

First through electrodes 200a may penetrate a first semiconductor substrate 100. The first through electrodes 200a may have pillar shapes that penetrate through the first semiconductor substrate 100. The first through electrodes 200a may include barrier layers formed on surfaces of the pillar shapes and buried conductive layers filling a space formed by the barrier layers. First insulating layers 250 may be interposed between the first semiconductor substrate 100 and the first through electrodes 200a.

Differently from the first through electrodes 210 of the semiconductor package 1 of FIG. 1, the first through electrodes 200a of the semiconductor package 3 may penetrate the first semiconductor substrate 100, an FEOL structure 112, and a BEOL structure 114. In other words, the first through electrodes 210 of the semiconductor package 1 of FIG. 1 may form the TSV structures 200 along with some of the metal line layers 220 and the via plugs 230. However, the first through electrodes 200a of the semiconductor package 3 form TSV structures may penetrate through the first semiconductor chip C1. First pads 240 may be electrically connected to the first through electrodes 200a. For example, a plurality of first pads 240 may be formed, and some of the plurality of first pads 240 may not be electrically connected to the first through electrodes 200a but may be electrically connected to line structures 220a and 230a electrically connected to the first semiconductor device 110. First back pads 420 may be formed on a first inactive surface 104 of the first semiconductor substrate 100 and may be electrically connected to the first through electrodes 200a.

In the semiconductor package 1 of FIG. 1, the FEOL structure 112 may be formed, the first through electrodes 210 may be formed, and some of the metal line layers 220 and the via plugs 230 and the first through electrodes 210 may form the TSV structures 200. In the semiconductor package 3 of FIG. 3, The FEOL structure 112 and the BEOL structure 114 may be formed, and then the first through electrodes 200a may be formed to form the TSV structures. Although not separately shown in FIG. 3, before the FEOL structure 112 is formed, through electrodes penetrating through the first semiconductor substrate 100 may be formed, and conductive lines or conductive plugs formed in the FEOL structure 112 and metal line layers 220 and via plugs 230 may form the TSV structures. In other words, the TSV structures may correspond to all types of conductive structures that penetrate through the first semiconductor chip C1 regardless of a detailed structure.

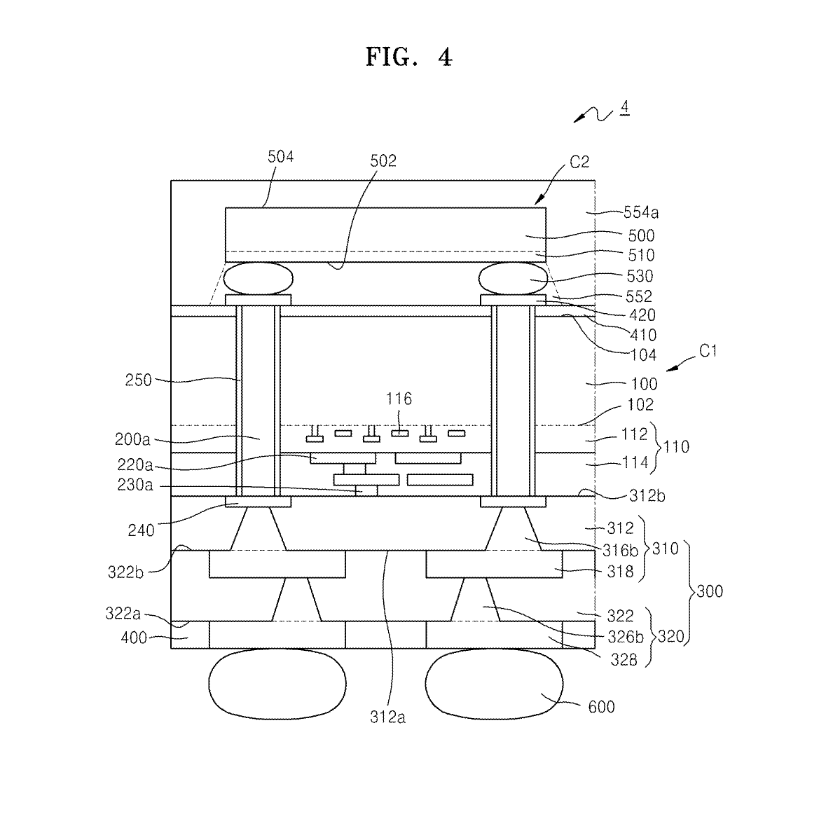

FIG. 4 is a cross-sectional view illustrating a semiconductor package 4 according to example embodiment of the inventive concepts. The same descriptions of the semiconductor package 4 of FIG. 4 as those of the semiconductor package 3 of FIG. 3 are omitted herein.

Referring to FIG. 4, the semiconductor package 4 may include first and second semiconductor chips C1 and C2. A printed circuit structure 300 may be attached onto the first semiconductor chip C1. The second semiconductor chip C2 may be attached onto the first semiconductor chip C1. The printed circuit structure 300 and the second semiconductor chip C2 may be respectively attached onto opposite surfaces of the first semiconductor chip C1.

A mold layer 554a may be formed on a first inactive surface 104 of a first semiconductor substrate 100. The mold layer 554a may cover all portions of the second semiconductor chip C2.

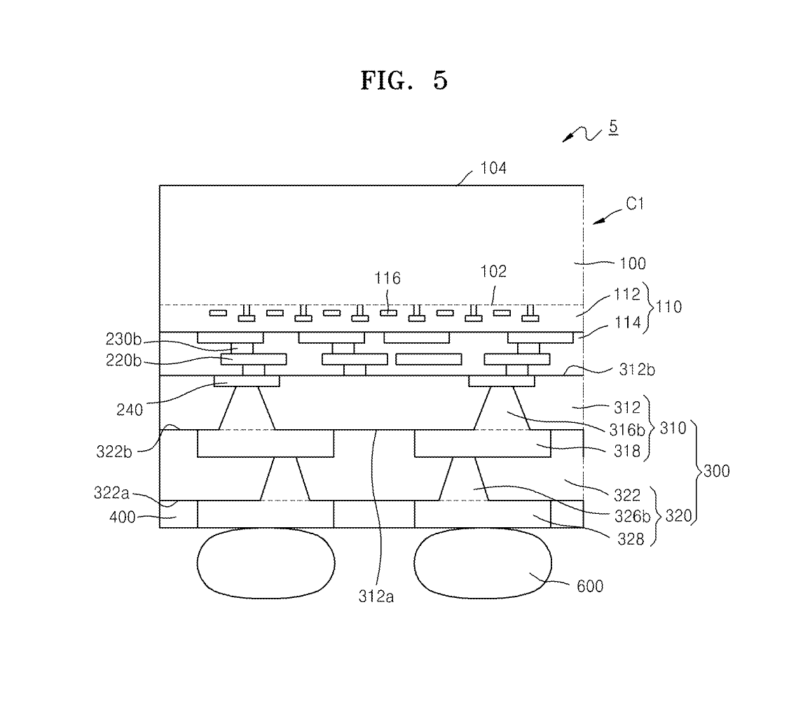

FIG. 5 is a cross-sectional view illustrating a semiconductor package 5 according to example embodiments of the inventive concepts.

Referring to FIG. 5, the semiconductor package 5 may include a first semiconductor chip C1. A printed circuit structure 300 may be attached onto the first semiconductor chip C1.

The first semiconductor chip C1 may include a first semiconductor substrate 100 and a first semiconductor device 110. The first semiconductor substrate 100 has a first active surface 102 and a first inactive surface 104 that are opposite to each other. The first active surface 102 and the first inactive surface 104 may be respectively referred to as first and second surfaces. The first semiconductor device 110 may be formed on the first active surface 102 of the first semiconductor substrate 100. The first semiconductor chip C1 may further include first pads 240 that are electrically connected to the first semiconductor device 110. The first semiconductor device 110 may include an FEOL structure 112 and a BEOL structure 114 formed on the FEOL structure 112.

The FEOL structure 112 may include a plurality of individual devices 116 of various types. The BEOL structure 114 may include a plurality of line structures 220b and 230b that electrically connect the individual devices 116 formed in the FEOL structure 112 to other lines formed on the first semiconductor substrate 100. The plurality of line structures 220b and 230b may include metal line layers 220b and via plugs 230b. The metal line layers 220b and the via plugs 230b may include barrier layers used for lines and metal layers used for lines. The BEOL structure 114 may further include a passivation layer that protects the line structures 220b and 230b and other structures formed under the line structures 220b and 230b from external shock or moisture.

The first pads 240 may be formed on the first active surface 102 of the first semiconductor substrate 100 of the first semiconductor chip C1. The first pads 240 may be formed on the BEOL structure 114 formed on the first active surface 102. The first pads 240 may be electrically connected to the line structures 220b and 230b.

The printed circuit structure 300 may include at least one of printed circuit layers 310 and 320. For example, the printed circuit structure 300 may include two printed circuit layers 310 and 320, e.g., first printed circuit layers 310 and second printed circuit layers 320. The first and second printed circuit layers 310 and 320 may respectively include first and second resin layers 312 and 322, first and second via electrodes 316b and 326b, and first and second line layers 318 and 328. In other words, the first printed circuit layers 310 may include the first resin layer 312, the first via electrodes 316b, and the first line layers 318, and the second printed circuit layers 320 may include the second resin layer 322, the second via electrodes 326b, and the second line layers 328. The first via electrodes 316b may be electrically connected to the first pads 240. The first via electrodes 316b may directly contact the first pads 240.

The first and second printed circuit layers 310 and 320 may be attached to face an upper surface 312a of the first resin layer 312 and a lower surface 322b of the second resin layer 322. The printed circuit structure 300 may be attached to the first semiconductor chip C1 so that a lower surface 312b of the first resin layer 312 faces the first active surface 102 of the first semiconductor substrate 100. The printed circuit structure 300 may be formed in direct contact with the first semiconductor chip C1. In other words, the lower surface 312b of the first resin layer 312 may surface-contact the first semiconductor chip C1.

A solder resist layer 400 may further be formed to cover a surface of the printed circuit structure 300 that is opposite to a surface of the printed circuit structure 300 facing the first semiconductor chip C1, e.g., an upper surface 322a of the second resin layer 322, and expose portions of the second line layers 328.

External connection terminals 600 may be formed on the surface of the printed circuit structure 300 that is opposite to the surface of the printed circuit structure 300 facing the first semiconductor chip C1, e.g., on the upper surface 322a of the second resin layer 322, to be electrically connected to the first and second via electrodes 316b and 326b and the first and second line layers 318 and 328. The external connection terminals 600 may be attached onto portions of the second line layers 328 of the second printed circuit layers 320 to be electrically connected to the second line layers 328.

Although not shown in FIG. 5, the semiconductor package 5 may further include an encapsulating layer which protects both surfaces of the first semiconductor chip C1 and the first inactive surface 104 of the first semiconductor substrate 100.

In the semiconductor package 5, the printed circuit structure 300 may be attached to face a surface of the first semiconductor chip C1, e.g., the first active surface 102 of the first semiconductor substrate 100. The printed circuit structure 300 may be directly attached onto the first semiconductor chip C1 to perform the same function as a PCB. If a PCB is used, connection bumps and an underfill material filling a space between the first semiconductor chip C1 and the PCB may be required between the first semiconductor chip C1 and the PCB. However, if the printed circuit structure 300 is attached onto the first semiconductor chip C1 to directly surface-contact the first semiconductor chip C1, the connection bumps or the underfill material may not be used. Therefore, manufacturing cost may be reduced, and a total height of the semiconductor package 5 may be reduced.

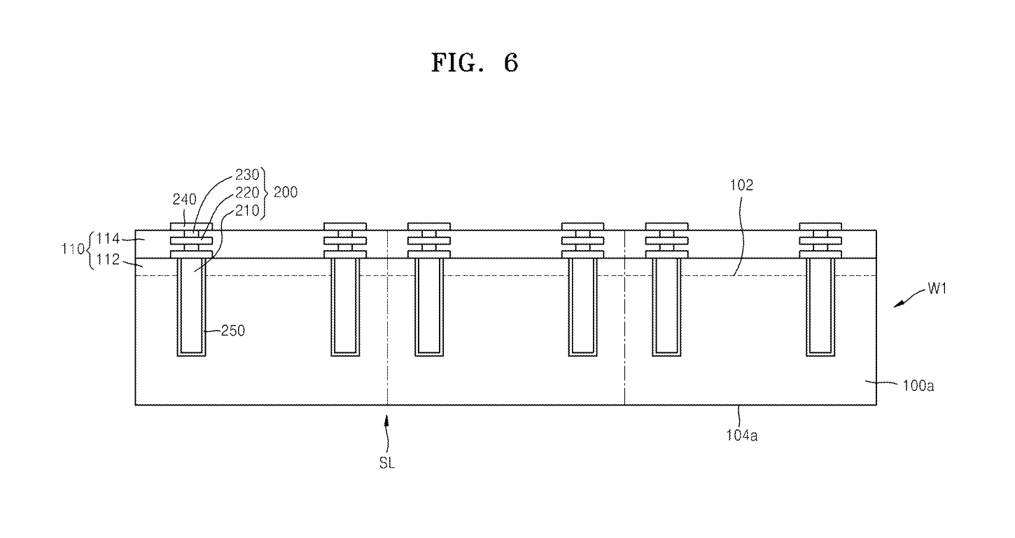

FIGS. 6 through 18 are cross-sectional views illustrating a method of manufacturing a semiconductor package, according to example embodiments of the inventive concepts.

FIG. 6 is a cross-sectional view illustrating a process of providing a first wafer W1 on which a first semiconductor device 110 is formed, according to an example embodiments of the inventive concepts.

Referring to FIG. 6, the first wafer W1, on which the first semiconductor device 110 is formed, may be provided. The first wafer W1 may include a first reserved semiconductor substrate 100a having a first active surface 102 and a first reserved inactive surface 104a that are opposite to each other. The first semiconductor device 110 may be formed on the first active surface 102 of the first reserved semiconductor substrate 100a. A plurality of semiconductor devices 110 that may be divided by a scribe line (SL) may be formed on the first wafer W1. The first semiconductor device 110 may include an FEOL structure 112 and a BEOL structure 114 formed on the FEOL structure 112. The FEOL structure 112 may include a plurality of individual devices of various types, as shown in FIG. 1. The BEOL structure 114 may include a plurality of line structures 220 and 230 that connect the individual devices formed in the FEOL structure 110 to other lines. The plurality of line structures 220 and 230 may include metal line layers 220 and via plugs 230.

The first wafer W1 may include first through electrodes 210 that extend from a surface of the first wafer W1, on which the first semiconductor device 110 is formed, into the first wafer W1. In other words, the first through electrodes 210 may be formed in the first wafer W1 to extend from the first active surface 102 of the first reserved semiconductor substrate 100a into the first reserved semiconductor substrate 100a. First insulating layers 250 may be interposed between the first reserved semiconductor substrate 100a and the first through electrodes 210. The first through electrodes 210 may form TSV structures 200 along with some of the metal line layers 220 and the via plugs 230. The TSV structures 200 may be electrically connected to or insulated from the first semiconductor device 110. For example, a plurality of TSV structures 200 may be formed, some of the TSV structures 200 may be electrically insulated from the first semiconductor device 110, and the other TSV structures 200 may be electrically connected to the first semiconductor device 110. Alternatively, all of the TSV structures 200 may be electrically insulated from the first semiconductor device 110 or may be electrically connected to the first semiconductor device 110.

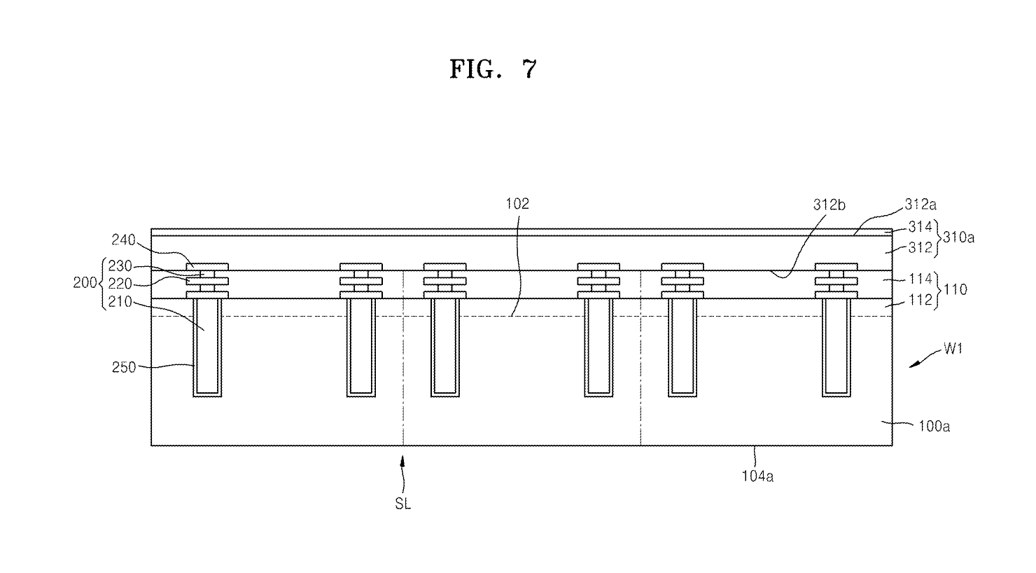

FIG. 7 is a cross-sectional view illustrating a process of attaching a first copper clad laminate 310a according to example embodiments of the inventive concepts.

Referring to FIG. 7, the first copper clad laminate 310a may be attached onto the first wafer W1. The first copper clad laminate 310a may include a first resin layer 312 and a first copper clad layer 314. A metal, such as copper, may be formed into a foil and then attached onto the first resin layer 312 to form the first copper clad laminate 310a. The first resin layer 312 may be formed of phenol, epoxy, polyimide, or the like. For example, the first resin layer 312 may include at least one material selected from FR4, tetrafunctional epoxy, polyphenylene ether, epoxy/polyphenylene oxide, bismaleimide triazine, thermount, cyanate ester, polyimide, and liquid crystal polymer. The first copper clad layer 314 may be formed of copper, nickel, stainless steel, or beryllium copper. A material that forms the first resin layer 312 may be provided in a B-stage state and then formed into laminates to form the first copper clad laminate 310a. Here, the B-stage state refers a state in which a solvent is removed in an A stage state that is an initial reaction state of a thermosetting resin but is not melted without being hardened, swells from the solvent, and is not dissolved.

Heat may be applied to the first copper clad laminate 310a, and then pressure may be applied to soften the first resin layer 312 and thus a laminate may be attached on the first wafer W1. The first resin layer 312 has upper and lower surfaces 312a and 312b that are opposite to each other. The first copper clad laminate 310a may be attached onto the first wafer W1 such that the lower surface 312b of the first resin 312 faces the first wafer W1.

The first copper clad laminate 310a may be attached onto the first wafer W1 so that the first resin 312 directly contacts a surface of the first wafer W1. Therefore, the lower surface 312b of the first resin 312 may surface-contact the surface of the first wafer W1. Also, after the first resin layer 312 is softened, the first copper clad laminate 310a may be attached onto the first wafer W1. Therefore, even if the surface of the first wafer W1 has step differences like first pads 240, the first copper clad laminate 310a may be attached onto the surface of the first wafer W1 not to form an empty space between the first copper clad laminate 310a and the first wafer W1.

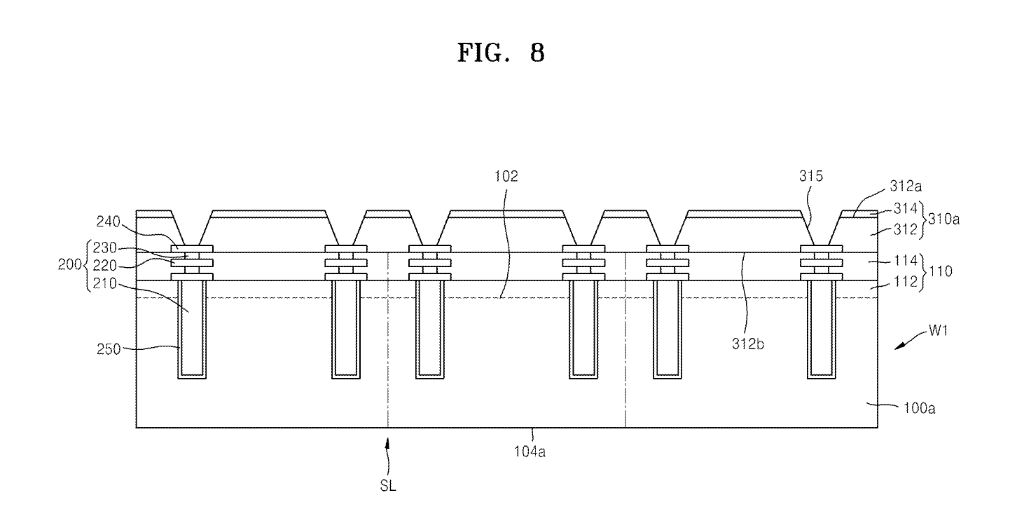

FIG. 8 is a cross-sectional view illustrating a process of forming first through holes 315, according to example embodiments of the inventive concepts.

Referring to FIG. 8, the first through holes 315 may be formed to penetrate through the first copper clad laminate 310a. The first pads 240 formed on the first wafer W1 may be exposed through the first through holes 315. In other words, the first through holes 315 may penetrate through the first copper clad laminate 310a to expose the first pads 240. The first through holes 315 may be formed by using a wet etching method, a dry etching method, mechanical drilling, or laser drilling. The laser drilling may be performed by using a CO₂ laser, a YAG laser, an excimer laser, a Cu-vapor laser, or a hybrid thereof. If the first through holes 315 are formed by using the laser drilling, the first through holes 315 may have cross-section areas that narrow until the first pads 240 are exposed from the first copper clad layer 314.

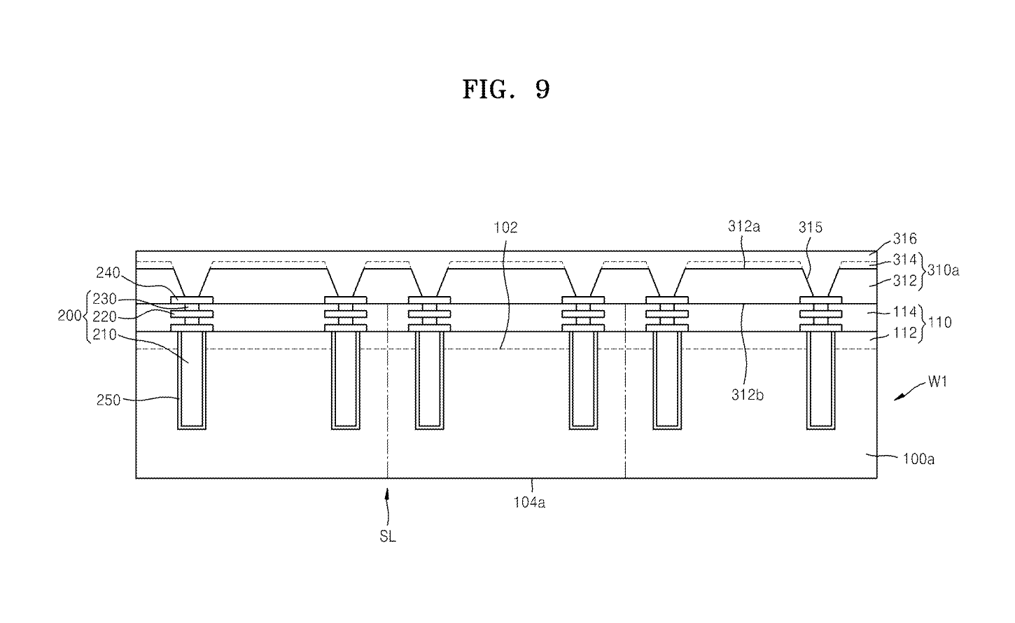

FIG. 9 is a cross-sectional view illustrating a process of forming a first plating layer 316, according to example embodiments of the inventive concepts.

Referring to FIG. 9, the first plating layer 316 may be formed on the first copper clad laminate 310a in which the first through holes 315 are formed. The first plating layer 316 may fill the first through holes 315 and cover a surface of the first copper clad layer 314. Therefore, the first plating layer 316 may contact the first pads 240 exposed through the first through holes 315. The first plating layer 316 may be formed of substantially the same material as that of the first copper clad layer 314. For example, the first plating layer 316 may be formed of copper, nickel, stainless steel, or beryllium copper. If the first plating layer 316 and the first copper clad layer 314 may be formed of the same type of material, the first plating layer 316 and the first copper clad layer 314 may be formed into a single body not to be separated from each other. Plating may be performed by using the first pads 240 and the first copper clad layer 314 as seeds to form the first plating layer 316. The first plating layer 316 may be formed by using immersion plating, electroless plating, electroplating, or a combination thereof.

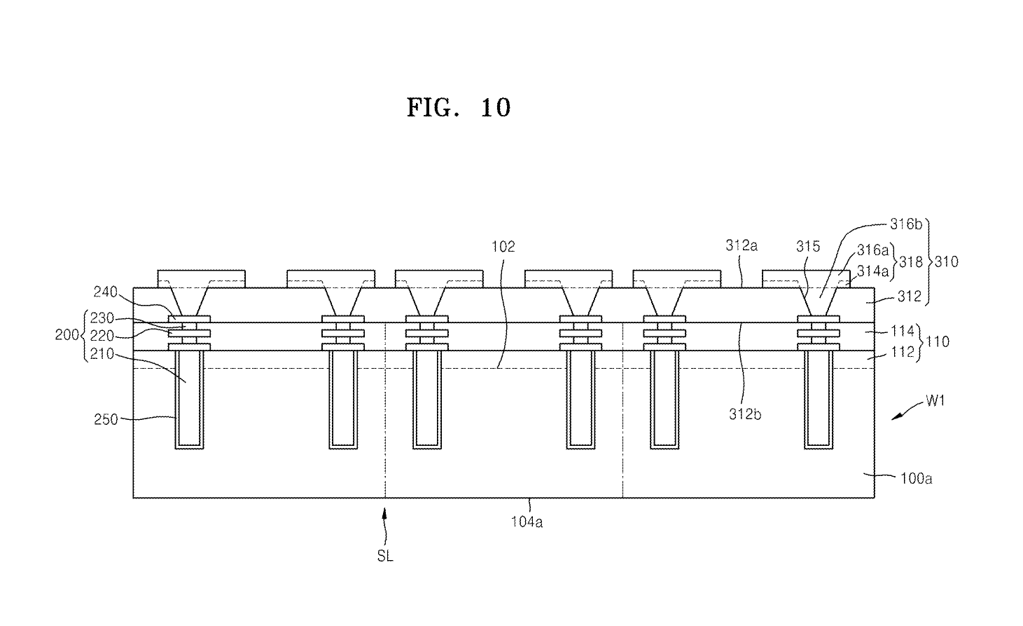

FIG. 10 is a cross-sectional view illustrating a process of forming a first printed circuit layer 310, according to example embodiments of the inventive concepts.

Referring to FIGS. 9 and 10, portions of the first plating layer 316 and the first copper clad layer 314 may be removed to expose portions of the upper surface 312a of the first resin layer 312. A chemical etching method may be used to remove the portions of the first plating layer 316 and the first copper clad layer 314. An etchant, such as ferric chloride, hydrogen peroxide/sulphuric acid, chromic-sulphuric acid, cupric chloride, ammonium persulphate, or alkaline ammoniacal/ammonium chloride, may be used for the chemical etching method of removing the portions of the first plating layer 316 and the first copper clad layer 314. Portions of the first plating layer 316, which remain in the first through holes 315 after removing the portions of the first plating layer 316 and the first copper clad layer 314, may be referred to as first via electrodes 316b. Remaining portions of the first plating layer 316 and the first copper clad layer 314 other than the portions of the first plating layer 316 and the first copper clad layer 314 remaining in the first through holes 315, e.g., portions 316a of the first plating layer 316 remaining on the upper surface 312a of the first resin layer 312 and portions 314a of the first copper clad layer 314 remaining on the upper surface 312a of the first resin layer 312, may be referred to as first line layers 318. The first resin layer 312, the first via electrodes 316b, and the first line layers 318 may be together referred to as the first printed circuit layer 310. The first line layers 318 may be electrically connected to the first via electrodes 316b. The first via electrodes 316b may be electrically connected to the first pads 240. The first via electrodes 316b may be formed in the first through holes 315 exposing the first pads 240, and thus directly contact the first pads 240.

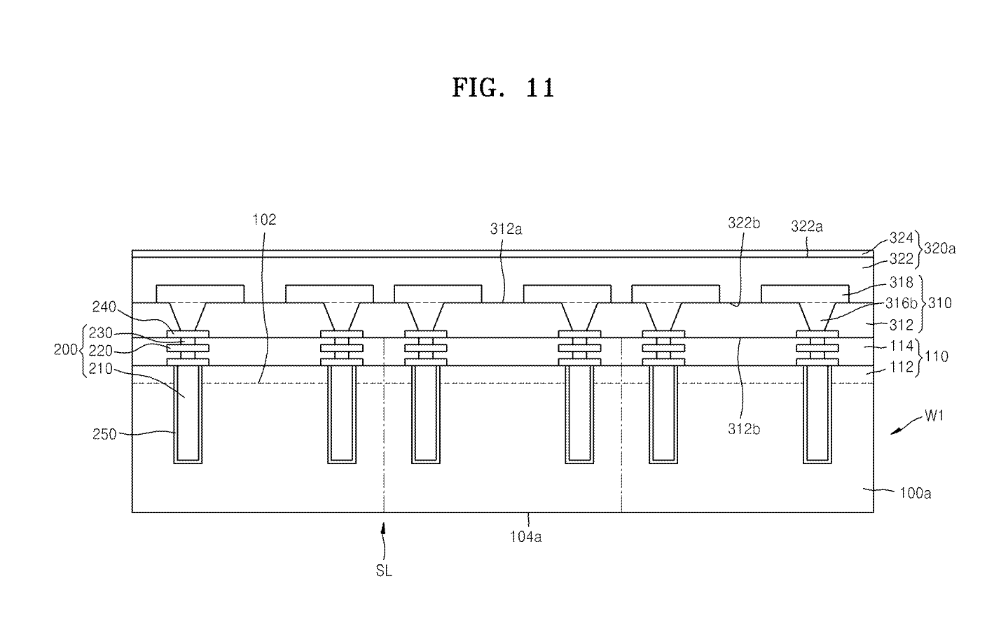

FIG. 11 is a cross-sectional view illustrating a process of attaching a second copper clad laminate 320a according to example embodiments of the inventive concepts.

Referring to FIG. 11, the second copper clad laminate 320a may be attached onto the first printed circuit layer 310. The second copper clad laminate 320a may include a second resin layer 322 and a second copper clad layer 324. The second copper clad laminate 320a may be formed of the same material as the first copper clad laminate 310a of FIG. 7 by using the same method for forming the first copper clad laminate 310a of FIG. 7. To soften the second resin layer 322, heat and pressure may be applied to the second copper clad laminate 320a to attach the second copper clad laminate 320a onto the first printed circuit layer 310. The second resin layer 322 has upper and lower surfaces 322a and 322b that are opposite to each other, and the second copper clad layer 324 may be attached onto the upper surface 322a of the second resin layer 322. The second copper clad laminate 320a may be attached onto the first printed circuit layer 310 such that the lower surface 322b of the second resin layer 322 faces the first printed circuit layer 310. Therefore, portions of the upper surface 312a of the first resin layer 312 that are exposed between the first line layers 318 may contact the lower surface 322b of the second resin layer 322.

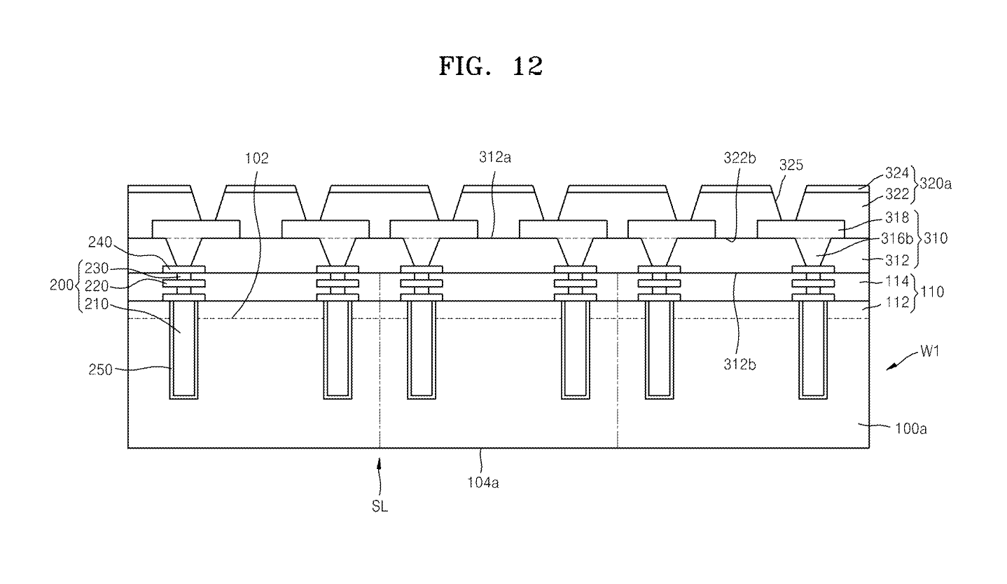

FIG. 12 is a cross sectional view illustrating a process of forming second through holes 325, according to example embodiments of the inventive concepts.

Referring to FIG. 12, the second through holes 325 may be formed to penetrate the second copper clad laminate 320a. Portions of the first line layers 318 of the first printed circuit layer 310 may be exposed through the second through holes 325. In other words, the second through holes 325 may penetrate through the second copper clad laminate 320a to expose the portions of the first line layers 318. The second through holes 325 may be formed by using the same method as or a similar method to the method of forming the first through holes 315 of FIG. 8.

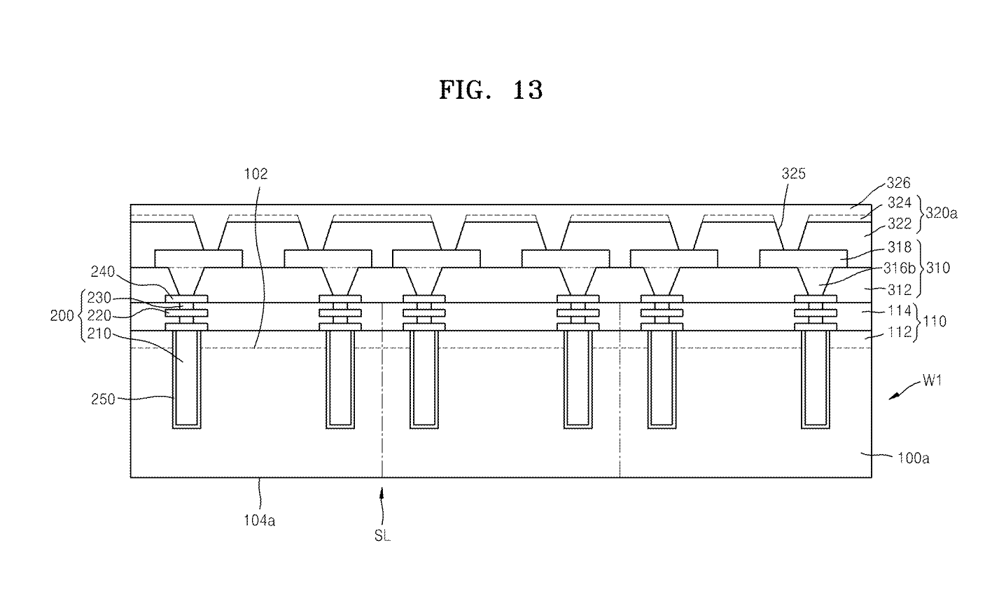

FIG. 13 is a cross-sectional view illustrating a process of forming a second plating layer 326, according to example embodiments of the inventive concepts.

Referring to FIG. 13, the second plating layer 326 may be formed on the second copper clad laminate 320a in which the second through holes 325 are formed. The second plating layer 326 may fill the second through holes 325 and cover a surface of the second copper clad layer 324. Therefore, the second plating layer 326 may contact the first line layers 318 exposed through the second through holes 325. The second plating layer 326 may be formed by using the same method as or a similar method to the method of forming the first plating layer 316 of FIG. 9.

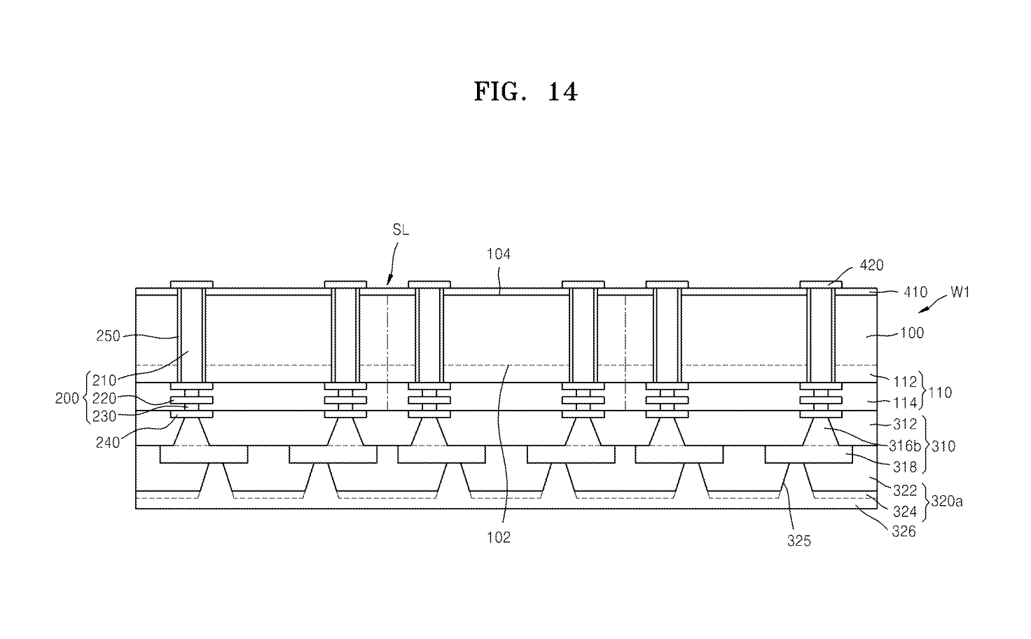

FIG. 14 is a cross-sectional view illustrating a process of exposing first through holes according to example embodiments of the inventive concepts.

Referring to FIGS. 13 and 14, the first wafer W1 may be reversed so that the second copper clad layer 324 faces down and the first reserved semiconductor substrate 100a faces up. A portion of a surface of the first wafer W1, which is opposite to a surface of the first wafer W1 on which the first semiconductor device 110 is formed, e.g., a portion of the first reserved semiconductor substrate 100a, may be removed to form the first semiconductor substrate 100. The portion of the first reserved semiconductor substrate 100a may be removed to form the first semiconductor substrate 100 until the first through electrodes 210 are exposed. The portion of the first reserved semiconductor substrate 100a may be removed by using a chemical mechanical polishing (CMP) process, an etch back process, or a combination thereof, to expose the first through electrodes 210. The surface of the first semiconductor substrate 100 exposing the first through electrodes 210 may be referred to as the first inactive surface 104 of the first semiconductor substrate 100.

After the first through electrodes 210 are exposed, a first back protective layer 410 may be formed to cover the first inactive surface 104 of the first semiconductor substrate 100 and expose the first through electrodes 210. The first back protective layer 410 may be formed by using a spin coating process or a spray process. The first back protective layer 410 may be formed of polymer. To form the first back protective layer 410, a polymer layer may be formed to fully cover the first inactive surface 104 of the first semiconductor substrate 100 and the exposed portions of the first through electrodes 210, and then a portion of the polymer layer may be etched back to expose the first through electrodes 210.

After the first back protective layer 410 is formed, first back pads 420 may be formed on the first inactive surface 104 of the first semiconductor substrate 100 to be electrically connected to the first through electrodes 210. The first back pads 420 may be formed after the first back protective layer 410 is formed or before the first back protective layer 410 is formed.

In FIGS. 9 through 14, the first through electrodes 210 may be formed before or after the first semiconductor device 110 is manufactured. Alternatively, to form the first through electrodes 210, a portion of the first reserved semiconductor substrate 100a may be removed to form the semiconductor substrate 100, through holes may be formed to expose portions of the line structures 220 and 230 from the first inactive surface 104 of the first semiconductor substrate, and the through holes may be filled with a conductive material.

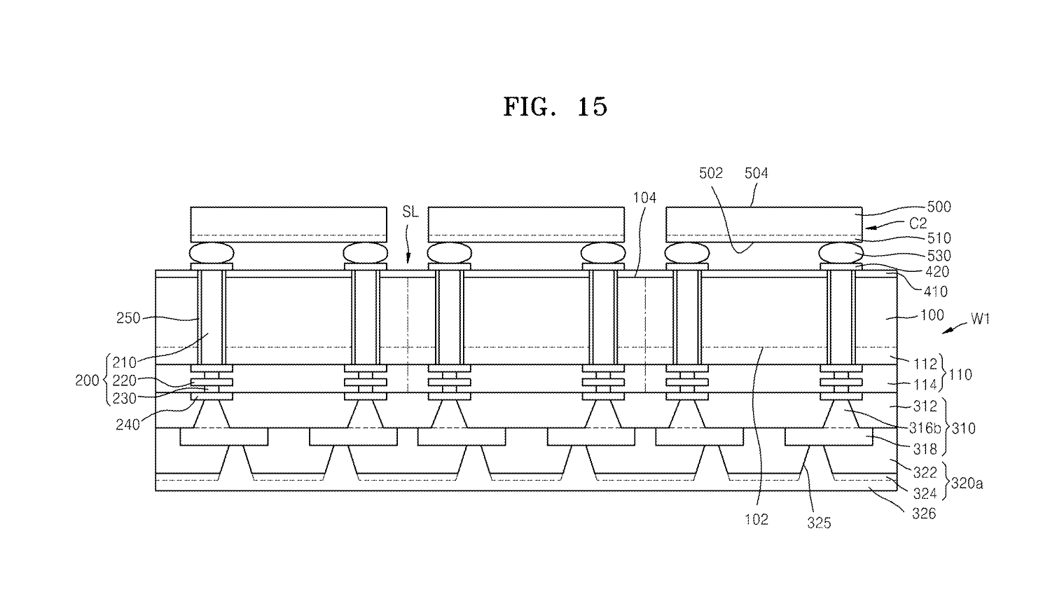

FIG. 15 is a cross-sectional view illustrating a process of attaching the second semiconductor chip C2, according to example embodiments of the inventive concepts.

Referring to FIG. 15, the second semiconductor chip C2 may be attached onto the first wafer W1 to be connected to the first back pads 420. The second semiconductor chip C2 may be attached onto the first wafer W1 to face the first inactive surface 104 of the first semiconductor substrate 100. The second semiconductor chip C2 may be electrically connected to the first through electrodes 210. The second semiconductor chip C2 may include a second semiconductor substrate 500 having a second active surface 502 and a second inactive surface 504 that are opposite to each other and a second semiconductor device 510 formed on the second active surface 502 of the second semiconductor substrate 500. The second semiconductor device 510 may be electrically connected to the first through electrodes 210. The first wafer W1 and the second semiconductor chip C2 may be attached to each other so that the first inactive surface 104 of the first semiconductor substrate 100 faces the second active surface 502 of the second semiconductor substrate 500.

The second semiconductor chip C2 may have a smaller area than the first semiconductor chip C1. In other words, the second active surface 502 or the second inactive surface 504 of the second semiconductor substrate 500 may have a smaller area than the first active surface 102 or the first inactive surface 104 of the first semiconductor substrate 100.

The second semiconductor chip C2 may be attached onto the first wafer W1 through connection bumps 530. The connection bumps 530 may be electrically connected to the second semiconductor device 510. The connection bumps 530 may contact the first back pads 420 to electrically connect the second semiconductor device 510 to the first through electrodes 210.

The second semiconductor chip C2 may be attached onto the first wafer W1 by using through electrodes (not shown). One or more semiconductor chips may be further attached onto the second semiconductor chip C2.

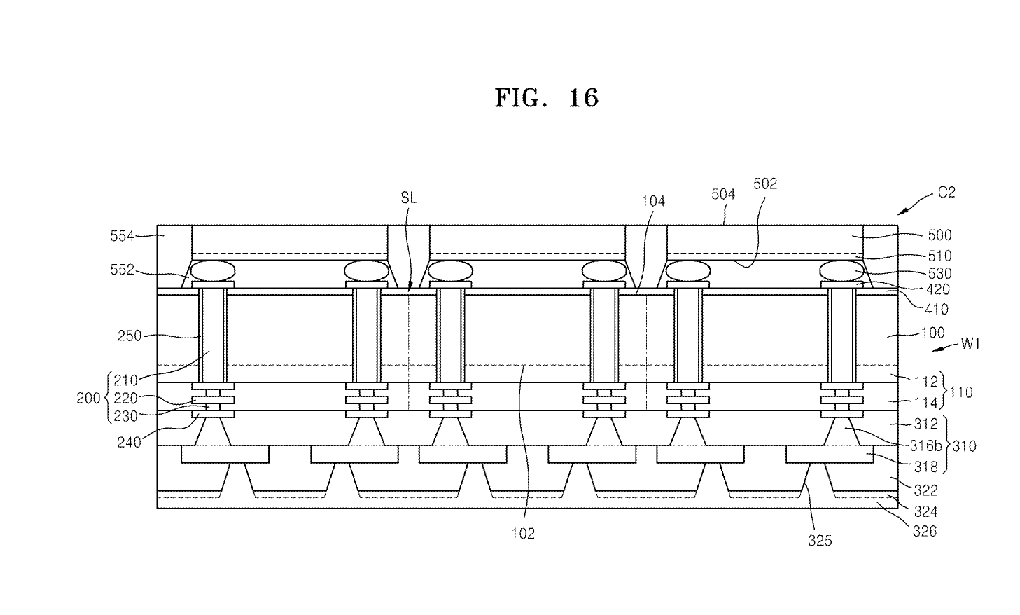

FIG. 16 is a cross-sectional view illustrating a process of forming a first underfill layer 552 and a mold layer 554 according to example embodiments of the inventive concepts.

Referring to FIG. 16, the first underfill layer 552 may be formed to fill a space between the second semiconductor chip C2 and the first wafer W1, and the mold layer 554 may be formed to cover the first inactive surface 104 of the first semiconductor substrate 100. The mold layer 554 may enclose the second semiconductor chip C2 to expose a surface of the second semiconductor chip C2 that is opposite to a surface of the second semiconductor chip C2 facing the first wafer W1, e.g., the second inactive surface 504 of the second semiconductor substrate 500. The first underfill layer 552 may be formed of an epoxy resin. The mold layer 554 may be formed of an epoxy mold compound (EMC). Alternatively, the first underfill layer 552 may be a mold underfill (MUF) that is formed of the same material as that of which the mold layer 554 is formed.

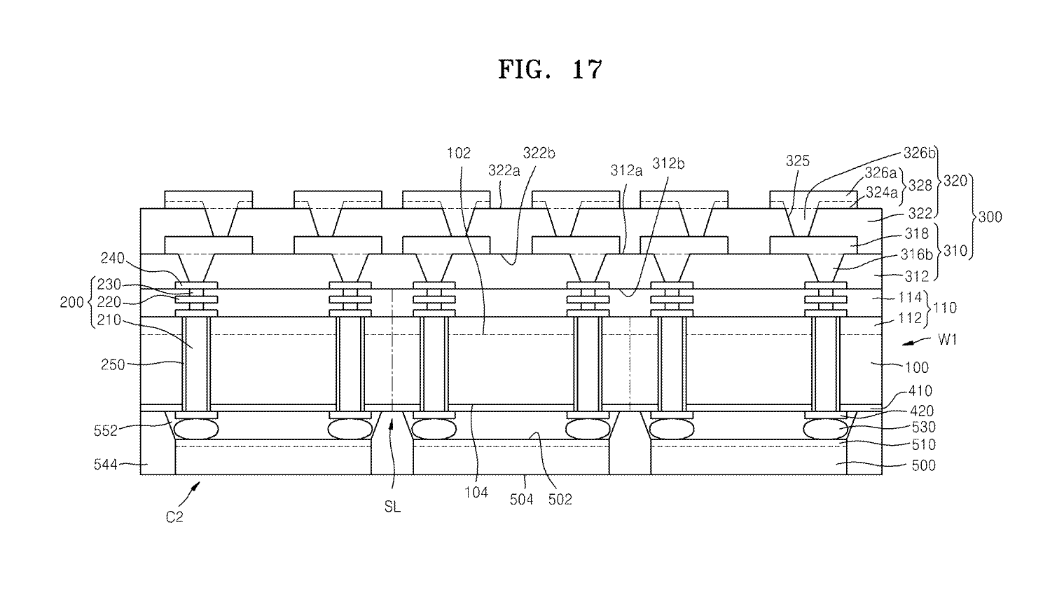

FIG. 17 is a cross-sectional view illustrating a process of forming a printed circuit structure 300, according to example embodiments of the inventive concepts.

Referring to FIGS. 16 and 17, the first wafer W1 may be reversed again so that the second semiconductor chip C2 faces down. Portions of the second plating layer 326 and the second copper clad layer 324 may be removed to expose portions of the upper surface 322a of the second resin layer 322. A chemical etching method may be used to remove the portions of the second plating layer 326 and the second copper clad layer 324. Portions of the second plating layer 326 remaining in the second through holes 325 through the removal of the portions of the second plating layer 326 and the second copper clad layer 324 may be referred to as second via electrodes 326b. Portions of the second plating layer 326 and the second copper clad layer 324 other the portions of the second plating layer 326 and the second copper clad layer 324, e.g., portions 326a of the second plating layer and portions 324a of the second copper clad layer 324 remaining on the upper surface 322a of the second resin layer 322, may be together referred to as second line layers 328. The second resin layer 322, the second via electrodes 326b, and the second line layers 328 may be together referred to as a second printed circuit layer 320. The second line layers 328 may be electrically connected to the second via electrodes 326b. The second via electrodes 326b may be electrically connected to the first line layers 318. The first printed circuit layer 310 and the second printed circuit layer 320 may be both referred to as a printed circuit structure 300.

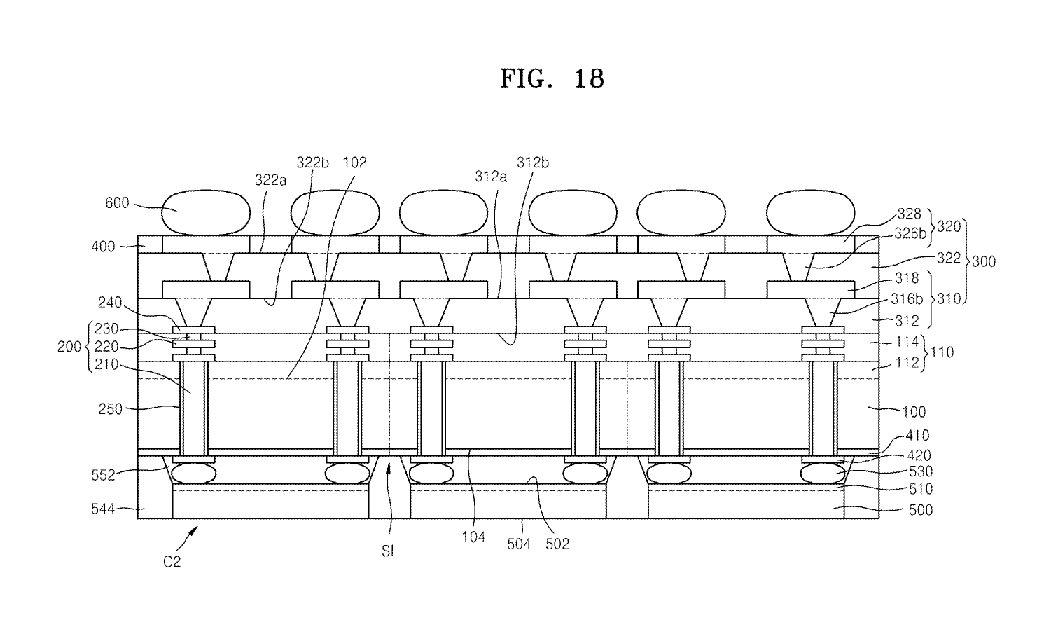

FIG. 18 is a cross-sectional view illustrating a process of forming external connection terminals 600, according to example embodiments of the inventive concepts.

Referring to FIG. 18, a solder resist layer 400 may be formed on the printed circuit structure 300 to cover the upper surface 322a of the second resin layer 322. The solder resist layer 400 may cover the upper surface 322a of the second resin layer 322 to expose at least portions of the second line layers 328. The solder resist layer 400 may cover sides of the second line layers 328, but may selectively cover upper surfaces of the second line layers 328 and expose portions of the second line layers 328. The external connection terminals 600 may be attached onto the portions of the second line layers 328 exposed through the solder resist layer 400. The external connection terminals 600 may be solder balls, bumps, or the like.

The first wafer W1 may be cut along a scribe line SL to form the first semiconductor chip C1 illustrated in FIG. 1. The first wafer W1, the printed circuit structure 300, and the mold layer 554 may be together cut along the scribe line SL to form the first semiconductor chip C1.

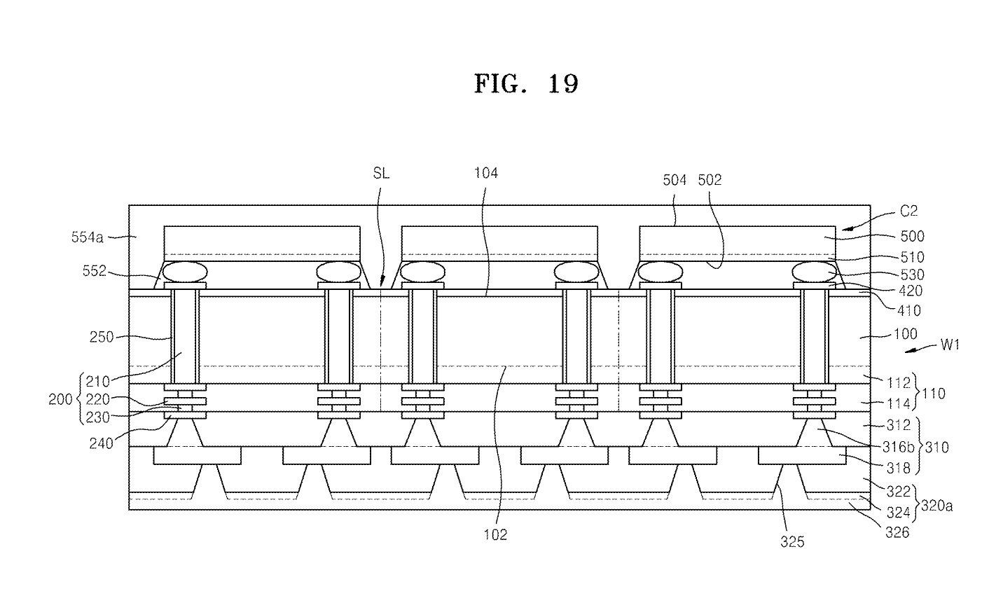

FIG. 19 is a cross-sectional view illustrating a method of manufacturing a semiconductor package, according to example embodiments of the inventive concepts. In detail, FIG. 19 is a cross-sectional view illustrating a process performed after the process of FIG. 15.

Referring to FIG. 19, a first underfill layer 552 may be formed to fill a space between a second semiconductor chip C2 and a first wafer W1, and a mold layer 554a may be formed to cover a first inactive surface 104 of a first semiconductor substrate 100 and the second semiconductor chip C2. The mold layer 554a may enclose the second semiconductor chip C2, e.g., a second inactive surface 504 of a second semiconductor substrate 500. In other words, the mold layer 554a may cover all portions of the second semiconductor chip C2. The semiconductor package 2 of FIG. 2 may be manufactured through the same processes as those described with reference to FIGS. 16 through 18.

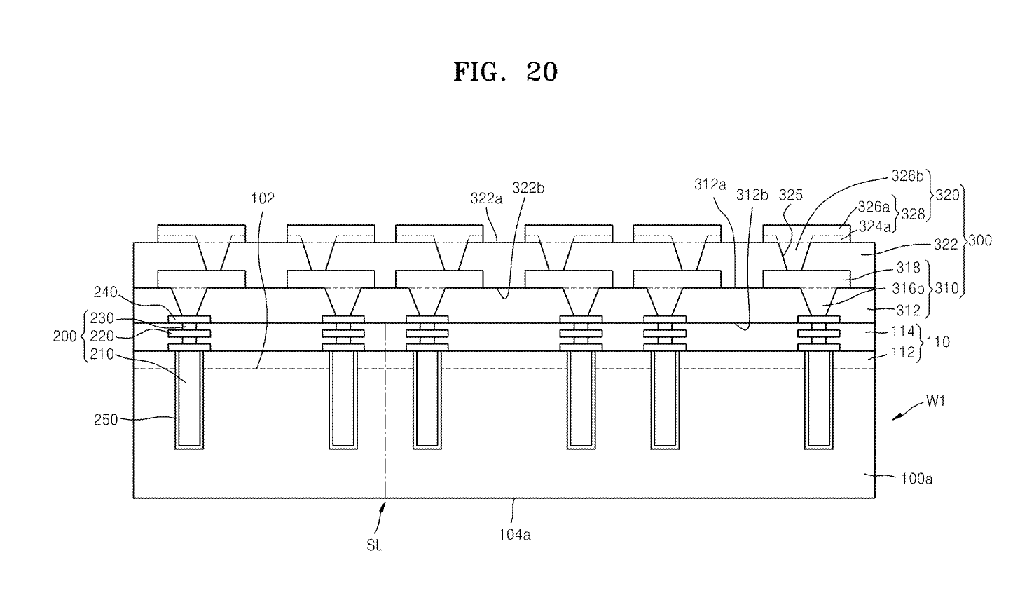

FIGS. 20 through 22 are cross-sectional views illustrating a method of manufacturing a semiconductor package, according to example embodiments of the inventive concepts.

FIG. 20 is a cross-sectional view illustrating a process of forming a printed circuit structure 300, according to example embodiments of the inventive concepts. In detail, FIG. 20 is a cross-sectional view illustrating a process performed after the process of FIG. 13.

Referring to FIGS. 13 and 20, portions of the second plating layer 326 and the second copper clad layer 324 may be removed to expose portions of the upper surface 322a of the second resin layer 322. Portions of the second plating layer 326 remaining in the second through holes 325 through the removal of the portions of the second plating layer 326 and the second copper clad layer 324 may be referred to as the second via electrodes 326b. Remaining portions of the second plating layer 326 and the second copper clad layer 324 other than the portions of the second plating layer 326 and the second copper clad layer 324 remaining in the second through holes 315, e.g., the portions 326a of the second plating layer 326 and the portions 324a of the second copper clad layer 324 remaining on the upper surface 322a of the second resin layer 322 may be together referred to as the second line layers 328. The second resin layer 322, the second via electrodes 326b, and the second line layers 328 may be together referred to as the second printed circuit layer 320. The second line layers 328 may be electrically connected to the second via electrodes 326b. The second via electrodes 326b may be electrically connected to the first line layers 318. The first printed circuit layer 310 and the second printed circuit layer 320 may be together referred to as the printed circuit structure 300.

A method of forming the first printed circuit layer 310 may be the same as that of forming the second printed circuit layer 320 except that the first through holes 315 expose the first pads 240, and the second through holes 325 expose the second line layers 328. Therefore, a process of forming one printed circuit layer 310 or 320 may be repeatedly performed so that the printed circuit structure 300 includes two or more printed circuit layers.

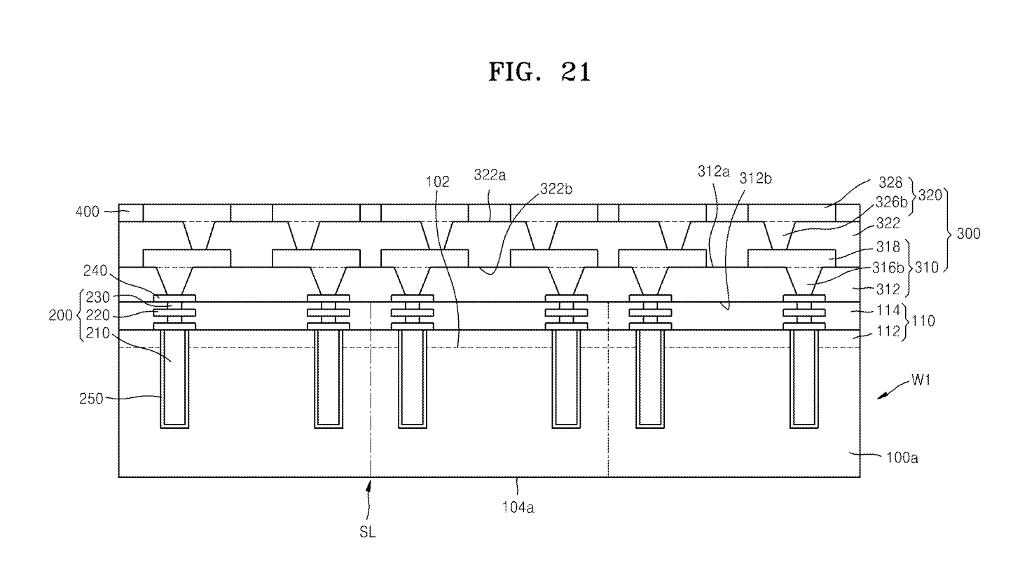

FIG. 21 is a cross-sectional view illustrating a process of forming a solder resist layer 400, according to example embodiments of the inventive concepts.

Referring to FIG. 21, the solder resist layer 400 may be formed on the printed circuit structure 300 to cover the upper surface 322a of the second resin layer 322 and expose portions of the second line layers 328. The solder resist layer 400 may enclose sides of the second line layers 318, but may selectively enclose portions of upper surfaces of the second line layers 328.

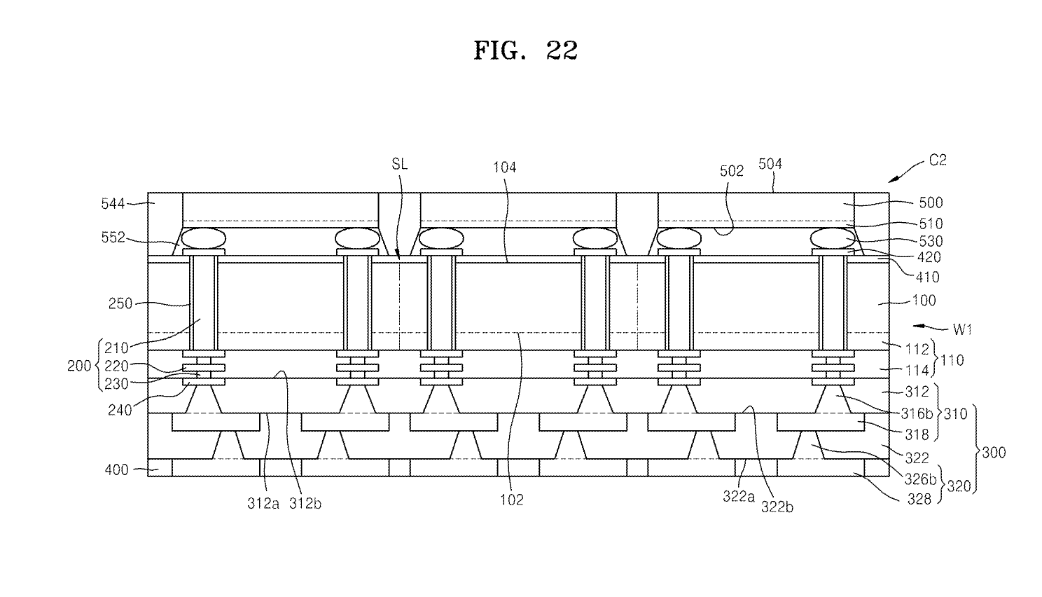

FIG. 22 is a cross-sectional view illustrating a process of forming a second semiconductor chip C2 and a mold layer 554, according to example embodiments of the inventive concepts.

Referring to FIGS. 21, and 22, the first wafer W1 may be reversed so that the printed circuit structure 300 faces down, and the first semiconductor substrate 100 faces up. According to a method as described with reference to FIGS. 14 and 15, a portion of the first wafer W1 may be removed to form the first semiconductor substrate 100 in which the first through electrodes 210 are exposed, and the first back protective layer 410 and the first back pads 420 may be formed. The second semiconductor chip C2 may be stacked on the first wafer W1 to be connected to the first back pads 420. The second semiconductor chip C2 may be attached onto the first wafer W1 with the connection bumps 530 interposed between the second semiconductor chip C2 and the first wafer W1. The second semiconductor chip C2 may also be electrically connected to the first through electrodes 210 through the connection bumps 530. After the second semiconductor chip C2 is attached onto the first wafer W1, the first underfill layer 552 may be formed to fill the space between the second semiconductor chip C2 and the first wafer W1, and the mold layer 554 may be formed to cover the first inactive surface 104 of the first semiconductor substrate 100.

As described with reference to FIG. 18, the external connection terminals 600 may be attached onto the portions of the second line layers 328 exposed through the solder resist layer 400. The first wafer W1 may be cut along the scribe line SL to form the semiconductor package 1 as illustrated in FIG. 1.

Differently than the first through electrodes 210 of the first wafer W1 illustrated in FIG. 6 that penetrate through the first semiconductor substrate 100 and the FEOL structure 112, in the semiconductor packages 3 and 4 illustrated in FIGS. 3 and 4, the first through electrodes 200a may be formed to penetrate through all of the first semiconductor substrate 100, the FEOL structure 112, and the BEOL structure 114. The manufacturing methods described with reference to FIGS. 7 through 22 may also be applied to the manufacturing of the semiconductor packages 3 and 4. Detailed descriptions thereof are omitted.

The first wafer W1, in which the first through electrodes 210 and the first insulating layers 250 are not formed, may be used, and the manufacturing methods described with reference to FIGS. 13, 17, and 18 may be applied to form the semiconductor package 5 of FIG. 5. A detailed description thereof is omitted herein.

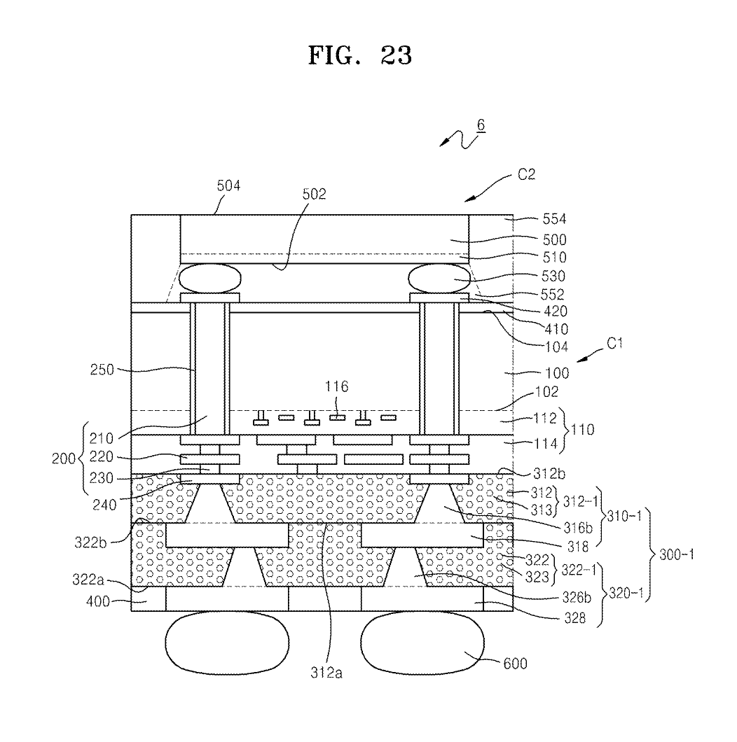

FIG. 23 is a cross-sectional view illustrating a semiconductor package 6 according to example embodiments of the inventive concepts.

Referring to FIG. 23, the semiconductor package 6 may further include reinforcement fillers 313 and 323 dispersed in resin layers 312 and 322. In other words, the semiconductor package 6 includes reinforcement resin layers 312-1 and 322-1 respectively having the reinforcement fillers 313 and 323. The reinforcement fillers 313 and 323 may be divided into a first reinforcement filler 313 filled in the first resin layer 312 and a second reinforcement filler 323 filled in the second resin layer 322. The reinforcement fillers 313 and 323 may have various shapes that are formed of paper, a cotton fabric, an asbestos sheet, glass, or the like. The reinforcement fillers 313 and 323 may be formed of fiberglass or fiber paper.

The reinforcement resin layers 312-1 and 322-1, including the reinforcement fillers 313 and 322, may be used, and the manufacturing methods described with reference to FIGS. 6 through 22 may be applied to manufacture the semiconductor package 6. Therefore, a detailed description thereof is omitted herein.

The semiconductor package 6 of FIG. 23, which is similar to the semiconductor package 1 of FIG. 1, may further include the reinforcement fillers 313 and 323. However, the semiconductor packages 2, 3, 4, and 5 of FIGS. 2 through 5 may further include the reinforcement fillers 313 and 323.

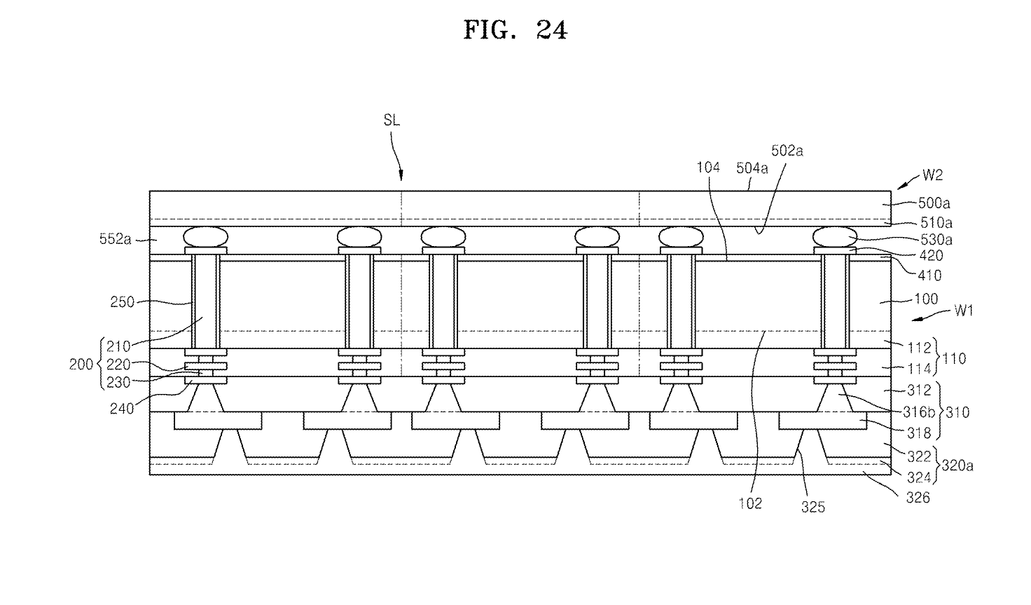

FIG. 24 is a cross-sectional view illustrating a method of manufacturing a semiconductor package, according to example embodiments of the inventive concepts. In detail, FIG. 24 is a cross-sectional view illustrating processes performed after the process of FIG. 14.

Referring to FIG. 24, a second wafer W2 may be attached onto a first wafer W1 to be connected to first back pads 420. The second wafer W2 may be attached onto the first wafer W1 to face a first inactive surface 104 of a first semiconductor substrate 100. The second wafer W2 may include a second semiconductor substrate 500a and a second semiconductor device 510a formed on a second active surface 502a of the second semiconductor substrate 500a. The second semiconductor device 510a may be electrically connected to first through electrodes 210. The first and second wafers W1 and W2 may be attached onto each other so that the first inactive surface 104 of the first semiconductor substrate 100 and the second active surface 502a of the second semiconductor substrate 500a face each other.

The second wafer W2 may be attached onto the first wafer W1 through connection bumps 530a. The connection bumps 530a may be electrically connected to the second semiconductor device 510a. The connection bumps 530a may contact the first back pads 420 to electrically connect the second semiconductor device 510a to the first through electrodes 210.

A second underfill layer 552a may be formed between the first and second wafers W1 and W2 to fill a space between the first and second wafers W1 and W2.

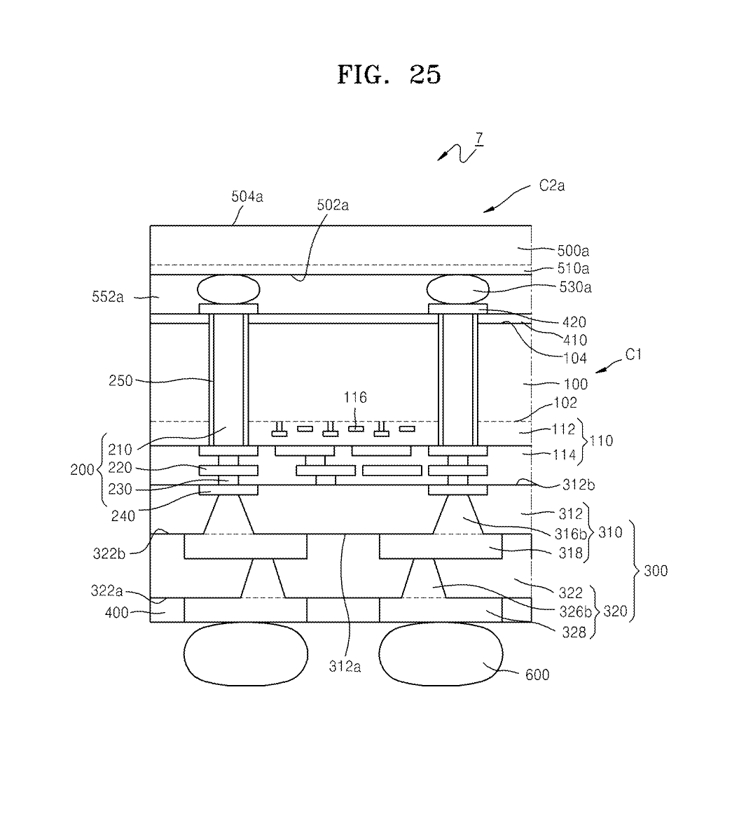

FIG. 25 is a cross-sectional view illustrating a semiconductor package 7 according to example embodiments of the inventive concepts.

Referring to FIG. 25, a second wafer W2 may be attached onto a first wafer W1, the manufacturing method described with reference to FIG. 17 or 18 may be performed, and the first and second wafers W1 and W2 may be cut along a scribe line SL to form the semiconductor package 7 including first and second semiconductor chips C1 and C2a.

The first and second semiconductors chip C1 and C2a may have the same area. In other words, a second active surface 502a or a second inactive surface 504a of the second semiconductor substrate 500a may have the same area as a first active surface 102 or a first inactive surface 104 of the first semiconductor device 100.

The semiconductor package 1 of FIG. 1 may be manufactured by using a wafer-to-chip (W-C) type stack package manufacturing method that is the manufacturing method described with reference to FIGS. 6 through 18. The semiconductor package 7 of FIG. 25 may be manufactured by using a wafer-to-wafer (W-W) type stack package manufacturing method that is the method described with reference to FIGS. 17 and 18.

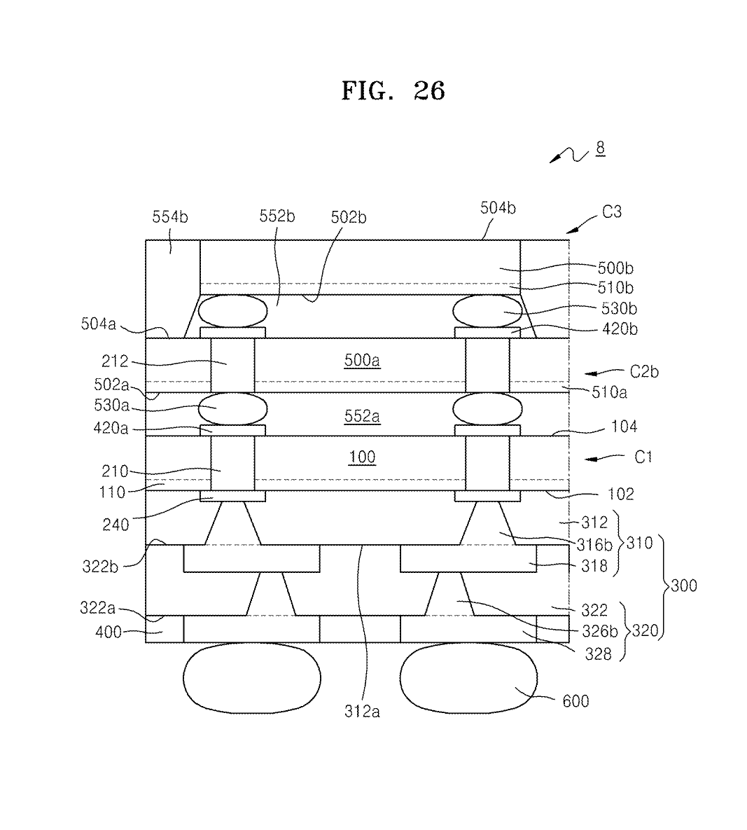

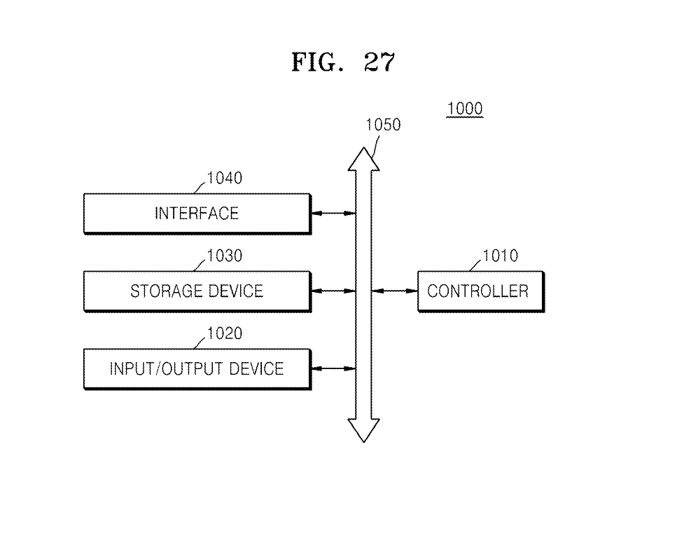

FIG. 26 is a cross-sectional view illustrating a semiconductor package 8 according to example embodiments of the inventive concepts. The semiconductor package 8 of FIG. 26 corresponds to a semiconductor package in which elements of the semiconductor package 7 of FIG. 27 are combined. Some of the elements of the semiconductor package 7 are omitted to simplify the semiconductor package 7. Therefore, repeated descriptions thereof are omitted herein.

Referring to FIG. 26, the semiconductor package 8 may include a first semiconductor chip C1, a second semiconductor chip C2b, and a third semiconductor chip C3. The second semiconductor chip C2b may have a second active surface 502a and a second inactive surface 504a that are opposite to each other. The second semiconductor chip C2b may include second through electrodes 212 that penetrate through a second semiconductor substrate 500 from the second active surface 502a to the second inactive surface 504a. The third semiconductor chip C3 may be attached onto the second semiconductor chip C2b to be electrically connected to the second through electrodes 212. The third semiconductor chip C3 may be attached onto the second semiconductor chip C2b through connection bumps 530b.

The first and second semiconductor chips C1 and C2b of the semiconductor package 8 may correspond to a stack of two first semiconductor chips C1 of the semiconductor package 1 of FIG. 1, the first and second semiconductor chips C1 and C2a of the semiconductor package 1 of FIG. 25, or the second semiconductor chips C2 of the semiconductor package 1 of FIG. 1. In other words, the second wafer W2 in which second through electrodes are formed may be attached by the manufacturing method described with reference to FIG. 24, and then the manufacturing method described with reference to FIGS. 15 and 16 may be applied to form the semiconductor package 8. Therefore, a detailed manufacturing method of the semiconductor package is omitted herein.

Although not shown in FIG. 26, the manufacturing method described with reference to FIG. 24 or the manufacturing method described with reference to FIGS. 15 and 16 may be repeatedly performed to manufacture a semiconductor package in which three or more semiconductor chips are stacked. Here, the other semiconductor chips except the semiconductor chip farthest away from a printed circuit structure may have through electrodes.

Stack types of semiconductor chips of the semiconductor packages 1, 2, 3, 4, 5, 6, 7, and 8 illustrated in FIGS. 1 through 5, 23, 25, and 26 are examples. Therefore, in every semiconductor package in which one or more semiconductor chips are attached onto a PCB, the PCB may be formed to be replaced with a printed circuit structure 300 or 300-1.

FIG. 27 is a schematic block diagram illustrating a system 1000 including a semiconductor package, according to example embodiments of the inventive concepts.

Referring to FIG. 27, the system 1000 may include a controller 1010, an input/output (I/O) device 1020, a storage device 1030, and an interface 1040. The system 1000 may be a mobile system or a system that transmits or receives information. According to example embodiments, the mobile system may be a personal digital assistant (PDA), a portable computer, a web tablet, a wireless phone, a mobile phone, a digital music player, or a memory card. The controller 1010 may control a program executed in the system 1000 and may be a microprocessor, a digital signal processor, a microcontroller, or a device similar thereto. The controller 1010 may include a semiconductor package according to the inventive concepts. For example, the controller 1010 may include the semiconductor package 1, 2, 3, 4, 5, 6, 7, or 8 illustrated in FIGS. 1 through 5, 23, 25, and 26. The I/O device 1020 may be used to input or output data of the system 1000. The system 1000 may be connected to an external device, e.g., a personal computer or a network, and exchanges data with the external device by using the I/O device 1020. The I/O device 1020 may be a keypad, a keyboard, or a display.

The storage device 1030 may store a code and/or data for an operation of the controller 1010 or data processed by the controller 1010. The storage device 1030 may include a semiconductor package according to the inventive concepts. For example, the storage device 1030 may include the semiconductor package 1, 2, 3, 4, 5, 6, 7, or 8 illustrated in FIGS. 1 through 5, 23, 25, and 26.

The semiconductor package according to the inventive concepts may be included in both the controller 1010 and the storage device 1030. For example, the semiconductor chips C1, C2, C2a, C2b, and C3 included in the semiconductor packages 1, 2, 3, 4, 5, 6, 7, and 8 illustrated in FIGS. 1 through 4, 23, 25, and 26 may be respectively the controller 1010 and/or the storage device 1030.

The interface 1040 may be a data transmission path between the system 1000 and another external device. The controller 1010, the I/O device 1020, the storage device 1030, and the interface 1040 may communicate with one another through a bus 1050. The system 1000 may be used in a mobile phone, an MP3 player, a navigation system, a portable multimedia player (PMP), a solid state disk (SSD), or household appliances.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
a first semiconductor chip including,
a first semiconductor substrate having a first active surface and a first inactive surface opposite to each other,
a first semiconductor device formed on the first active surface of the first semiconductor substrate,
first through electrodes penetrating through the first semiconductor substrate, and
pads electrically connected to one of the first semiconductor device and the first through electrodes;
a printed circuit structure on the first semiconductor chip, the printed circuit structure including,
at least one printed circuit layer having
a resin layer having upper and lower surfaces opposite to each other, the lower surface of the resin layer facing the first active surface of the first semiconductor substrate,
via electrodes penetrating through the resin layer to be electrically connected to the first semiconductor chip, and
line layers on the upper surface of the resin layer and connected to the via electrodes;
a second semiconductor chip attached to the first semiconductor chip, the second semiconductor chip facing the first inactive surface of the first semiconductor substrate and electrically connected to the first through electrodes; and
external connection terminals attached to a surface of the printed circuit structure, the external connection terminals electrically connected to the line layers and the via electrodes.

2. The semiconductor package of claim 1, wherein the via electrodes and the line layers comprise a same type of material, and the via electrodes are electrically connected to the pads.

3. The semiconductor package of claim 1, wherein the resin layer comprises reinforcement fillers.

4. The semiconductor package of claim 1, wherein the lower surface of the resin layer surface-contacts the first semiconductor chip.

5. The semiconductor package of claim 1, wherein the printed circuit structure further comprises a solder resist layer selectively covering a surface of the printed circuit structure while exposing portions of the line layers.

6. The semiconductor package of claim 5, wherein the external connection terminals are connected to the portions of the line layers exposed through the solder resist layer.

7. The semiconductor package of claim 1, wherein the second semiconductor chip includes,
a second active surface having a second semiconductor device thereon, the second active surface electrically connected to the first semiconductor chip through connection bumps, and
a second inactive surface opposite to the second active surface.

8. The semiconductor package of claim 7, wherein the first active surface of the first semiconductor chip has a same area as the second active surface of the second semiconductor chip.

9. The semiconductor package of claim 7, wherein an area of the first active surface of the first semiconductor chip is greater than an area of the second active surface of the second semiconductor chip.

10. The semiconductor package of claim 1, wherein the second semiconductor chip comprises:
a second semiconductor substrate having a second active surface and a second inactive surface opposite to each other;
a second semiconductor device on the second active surface; and
second through electrodes penetrating through the second semiconductor substrate from the second active surface to the second inactive surface, and
wherein the semiconductor package further comprises a third semiconductor chip on the second semiconductor chip and electrically connected to the second through electrodes.

11. A semiconductor package comprising:
a semiconductor substrate having first and second surfaces, the first and second surfaces opposite to each other;
a semiconductor device on the first surface of the semiconductor substrate;
pads on the first surface of the semiconductor substrate and electrically connected to the semiconductor device; and
at least one printed circuit layer including,
a resin layer,
via electrodes penetrating through the resin layer, and
line layers on the first resin layer, the line layers connected to the via electrodes and attached to the first surface of the semiconductor substrate,
wherein the via electrodes and the line layers include a same type of material, and the via electrodes are electrically connected to the pads.

12. The semiconductor package of claim 11, wherein the via electrodes and the line layers of the at least one printed circuit layer directly contact the resin layer.

13. The semiconductor package of claim 1, wherein the via electrodes directly contact the pads.

14. The semiconductor package of claim 11, wherein a plurality of printed circuit layers are formed, and resin layers of two adjacent printed circuit layers of the plurality of printed circuit layers surface-contact each other.

15. A semiconductor package comprising:
a first semiconductor structure including a first semiconductor substrate, the first semiconductor substrate including a first though electrode penetrating therethrough, the first through electrode including a first end and a second end opposite to each other;
a first printed circuit layer on the first semiconductor structure, the first printed circuit layer electrically connected to the first end of the first through electrode;
a second printed circuit layer on the first printed circuit layer, the second printed circuit layer electrically connected to the first through electrode; and
a second semiconductor structure electrically connected to the second end of the first through electrode.

16. The semiconductor package of claim 15, wherein at least one of the first and the second printed circuit layer includes,
a resin layer on the first semiconductor structure including a through hole; and
a line layer structure configured to fill the through hole.

17. The semiconductor package of claim 16, wherein the line layer includes,
a via electrode portion filling the through hole; and
a line layer portion on the via electrode portion and extending over an upper surface of the resin layer.

18. The semiconductor package of claim 17, wherein the line layer portion includes a copper clad layer and a first plating layer on the copper clad layer.

19. The semiconductor package of claim 15, further comprising:
a front pad on the first end of the first through electrode, the front pad configured to electrically connect the first end of the first through electrode to the first semiconductor structure.

20. The semiconductor package of claim 15, further comprising:
a back pad on the second end of the first through electrode, the back pad configured to electrically connect the second end of the first through electrode to the second semiconductor structure.
